(19) United States
(12) Patent Application Publication
(10) Pub. No.: US 2026/0215155 A1
(43) Pub. Date: Jul. 23, 2026

(54) ORGANIC LIGHT-EMITTING DIODE

(71) Applicant: LORDIN CO., LTD, Hwaseong-si Gyeonggi-do (KR)

(72) Inventors: Bu Bae PARK, Hwaseong-si Gyeonggi-do (KR); Ga Ram HAN, Osan-si Gyeonggi-do (KR); Min Sik MUN, Hwaseong-si Gyeonggi-do (KR)

(21) Appl. No.: 19/142,002

(22) PCT Filed: Dec. 20, 2023
(86) PCT No.: PCT/KR2023/021116

§ 371 Date: Jun. 20, 2025

(30) Foreign Application Priority Data
Dec. 20, 2022 (KR) 10-2022-0179379

(51) Int. Cl. H10K 85/60; C09K 11/06; H10K 50/11; H10K 85/30; H10K 101/40

(52) U.S. Cl. CPC H10K 85/658; C09K 11/06; H10K 85/342; H10K 85/346; H10K 85/615; H10K 85/654; C09K 2211/1007; C09K 2211/1011; C09K 2211/1018; C09K 2211/185; H10K 50/11; H10K 2101/40

(57) ABSTRACT

Provided in an organic light-emitting diode including a first electrode, a second electrode, and a light-emitting layer disposed between the first electrode and the second electrode, wherein the light-emitting layer includes a complex light-emitting compound designed to meet conditions stated in the detailed description.

### TECHNICAL FIELD

The present disclosure relates to an organic light-emitting diode including an organic light-emitting material having a long lifetime.

### BACKGROUND ART

An OLED (organic light-emitting diode) is a device in which holes injected from an anode and electrons injected from a cathode pass through a charge transport layer and combine in a light-emitting layer to form excitons and emit light, and was first reported in Appl. Phys. Lett 51, 913 by C. W. Tang in 1987. At that time, the light-emitting layer was formed with an Alq₃ single material. In J. Appl. Phys., Vol. 65, 3610 in 1989, it is disclosed that Alq₃ was doped with a small amount of DCM as a red light-emitting compound and a small amount of Coumarin 540 as a green light-emitting compound to adjust emission wavelengths and increase efficiency.

### DISCLOSURE

### Technical Problem

An object of the present disclosure is to provide an organic light-emitting diode capable of minimizing a decrease in light brightness even when driven for a long period of time by improving luminescence stability of a light-emitting body.

Objects of the present disclosure are not limited to the object mentioned above, and other objects and advantages of the present disclosure not mentioned herein may be understood by the following description, and will be more clearly understood by embodiments of the present disclosure. In addition, it may be readily seen that objects and advantages of the present disclosure may be embodied by means described in the claims and combinations thereof.

### Technical Solution

One embodiment of the present disclosure provides,
an organic light-emitting diode including: a first electrode; a second electrode; and a light-emitting layer disposed between the first electrode and the second electrode,
wherein the light-emitting layer includes a complex light-emitting compound,
the complex light-emitting compound includes an electron regulatory moiety and a light-emitting moiety,
the complex light-emitting compound includes a linking portion that links the electron regulatory moiety and the light-emitting moiety through a spiro bond,
the electron regulatory moiety is a substituted or unsubstituted aromatic ring having 6 to 50 carbon atoms or aromatic hetero-fused ring having 5 to 50 carbon atoms, or derived from organometallic compounds in which these and metals bond,
HOMO-LUMO gap energy of the electron regulatory moiety is larger than maximum emission wavelength energy of the light-emitting moiety, and
a LUMO energy level of the electron regulatory moiety is the same as or lower than a LUMO energy level of the light-emitting moiety.

### Advantageous Effects

An organic light-emitting diode including a complex light-emitting compound of the present disclosure minimizes a decrease in brightness even when driven for a long period of time by increasing luminescence stability of the device.

Specific effects of the present disclosure in addition to the above-described effect will be described together while describing specific details to carry out the present disclosure hereinafter.

### BRIEF DESCRIPTION OF DRAWINGS

FIG. 1 shows HOMO-LUMO energy levels of a general host and a general dopant, and HOMO-LUMO energy levels of a host and a complex light-emitting compound to be obtained through the present disclosure.

### BEST MODE

Hereinafter, embodiments of the present disclosure will be described in detail with reference to drawings so that those skilled in the art may readily carry out the present disclosure. The present disclosure may be embodied in various different forms, and is not limited to the embodiments described herein.

In the present specification, the term “substitution” means that a hydrogen atom bonding to a carbon atom in a compound is substituted with another substituent. The position where substitution occurs means a position at which the hydrogen atom is substituted. The position is not limited as long as it is a position where hydrogen at the position may be substituted with a substituent. When two or more substitutions occur, the two or more substituents may be the same as or different from each other.

In the present specification, the substituent when “substituted” may be, unless otherwise stated, one selected from the group consisting of, for example, deuterium, an alkyl group having 1 to 20 carbon atoms, a cycloalkyl group having 3 to 30 carbon atoms, a heterocycloalkyl group having 2 to 30 carbon atoms, an allyl group having 3 to 30 carbon atoms, an alkoxy group having 1 to 30 carbon atoms, a halogen group, a cyano group, a carboxyl group, a carbonyl group, an amine group, an alkyl amine group having 1 to 30 carbon atoms, a cycloalkyl amine group having 3 to 30 carbon atoms, a heterocycloalkyl amine group having 2 to 30 carbon atoms, a nitro group, an alkyl silyl group having 1 to 30 carbon atoms, a cycloalkyl silyl group having 3 to 30 carbon atoms, a heterocycloalkyl silyl group having 2 to 30 carbon atoms, an alkoxysilyl group having 1 to 30 carbon atoms, an aryl silyl group having 6 to 30 carbon atoms, an aryl group having 6 to 30 carbon atoms, an aryl amine group having 6 to 30 carbon atoms, a heteroaryl group having 2 to 30 carbon atoms, an aryl phosphine oxide group having 6 to 30 carbon atoms, an aryl phosphinyl group having 6 to 30 carbon atoms, an alkyl phosphine oxide group having 1 to 30 carbon atoms, a cycloalkyl phosphine oxide group having 3 to 30 carbon atoms, a heterocycloalkyl phosphine oxide group having 2 to 30 carbon atoms, an alkyl sulfonyl group having 1 to 30 carbon atoms, a cycloalkyl sulfonyl group having 3 to 30 carbon atoms, a heterocycloalkyl sulfonyl group having 2 to 30 carbon atoms, and combinations thereof, but is not limited thereto.

“Combinations thereof” in the definition of substituents of the present specification means that, unless otherwise defined, two or more divalent substituents are present, or two or more substituents are linked or fused for bonding.

In the present specification, a case of two substituents being linked to form a ring includes a case in which one of the two substituents is hydrogen, and the two substituents are linked as the hydrogen is removed.

In the present specification, alkyl includes cycloalkyl and heterocycloalkyl unless otherwise stated. In addition, for example, alkyl amine includes cycloalkyl amine and heterocycloalkyl amine unless otherwise stated.

In the present specification, “hetero” means, unless otherwise defined, including a heteroatom in one compound or substituent. The heteroatom means an atom that is not carbon and hydrogen among the atoms forming a heterocyclic compound. Examples thereof may include N, O, Si, Ge, S, P, B, Se, Te and the like, but are not limited thereto. When two or more heteroatoms are included in one compound or substituent, the included heteroatoms may be the same as or different from each other, and, for example, be one, or two or more types of heteroatoms. For example, heteroaryl or heterocycloalkyl includes at least one heteroatom as an atom forming the ring.

In the present specification, a ring includes a fused ring unless otherwise stated.

One embodiment of the present disclosure provides,
an organic light-emitting diode including: a first electrode; a second electrode; and a light-emitting layer disposed between the first electrode and the second electrode,
in which the light-emitting layer includes a complex light-emitting compound,
the complex light-emitting compound includes an electron regulatory moiety, a linking portion and a light-emitting moiety,
the light-emitting layer includes a complex light-emitting compound,
the complex light-emitting compound includes an electron regulatory moiety and a light-emitting moiety,
the complex light-emitting compound includes a linking portion that links the electron regulatory moiety and the light-emitting moiety through a spiro bond,
the electron regulatory moiety is a substituted or unsubstituted aromatic ring having 6 to 50 carbon atoms or aromatic hetero-fused ring having 5 to 50 carbon atoms, or derived from organometallic compounds in which these and metals bond,
HOMO-LUMO gap energy of the electron regulatory moiety is larger than maximum emission wavelength energy of the light-emitting moiety, and
a LUMO energy level of the electron regulatory moiety is the same as or lower than a LUMO energy level of the light-emitting moiety.

By the organic light-emitting diode using the complex light-emitting compound designed to meet the conditions described above, luminescence stability of the device increases, and an organic light-emitting diode that minimizes a decrease in brightness even when driven for a long period of time is obtained.

A dopant generally performs a decisive role in, in addition to emission wavelength and efficiency of an organic light-emitting diode, a property of decrease in the brightness depending on driving time of the device. The complex light-emitting compound is designed and developed to exhibit stable brightness even when driving the device for a long period of time by improving a deterioration mechanism and an energy transfer process of the dopant.

A process in which electrons and holes injected into a light-emitting layer combine in a host of the light-emitting layer to form excitons and the energy is transferred to a dopant is explained with a method by light of the following Mathematical Formula 1 (FRET, Forster Resonance Energy transfer) and a method by electron of the following Mathematical Formula 2 (Dexter Electron Transfer).

### PRET (Forster Resonance Energy Transfer)

$${k}_{ET} = ( \frac{1}{{r}^{6} {τ}_{D}} ) ( \frac{2.07 {κ}^{2} {Q}_{D} J}{128 {π}^{5} {N}_{A} {n}^{4}} ) \qquad [ Mathematical Formula 1 ]$$

### Dexter Electron Transfer

$${k}_{ET} ∝ J {exp}^{( - \frac{2 r}{L} )} \qquad [ Mathematical Formula 2 ]$$

K_{ET}: rate constant
r: distance between energy donor and energy acceptor
τ_{D}: PL decay time of energy donor
K: orientation factor
Q_{D}: PL quantum efficiency of energy donor
N_{A}: Avogadro number
n: refractive index
J: defined by Mathematical Formula 3.

$$J = \int {f}_{D} ( λ ) {ε}_{A} ( λ ) {λ}^{4} d λ \qquad [ Mathematical Formula 3 ]$$

f_{D}: emission spectrum of energy donor
ε_{A}: extinction coefficient depending on wavelength of energy acceptor
L: sum of Van der Waals radii
λ: wavelength

Once the dopant receives energy from the host, it becomes excited. In other words, this state is the same as a state in which one of the two electrons present at the HOMO (Highest Occupied Molecular Orbital) level of the dopant moves to the LUMO (Lowest Unoccupied Molecular Orbital) level. It takes from several nanoseconds to several milliseconds, varying depending on the spin state of the electron, for the electron at the LUMO level to come down to the HOMO level and stabilize again. Considering that the time taken for vibratory motion of a molecule is on the order of few picoseconds, the dopant in an excited state continuously interacts with surrounding molecules before being relaxed as light, which leads to creating new energy levels, producing chemical reactions, or being decomposed, and such a series of processes accelerate a decrease in the luminescence intensity depending on the driving time of an organic light-emitting diode.

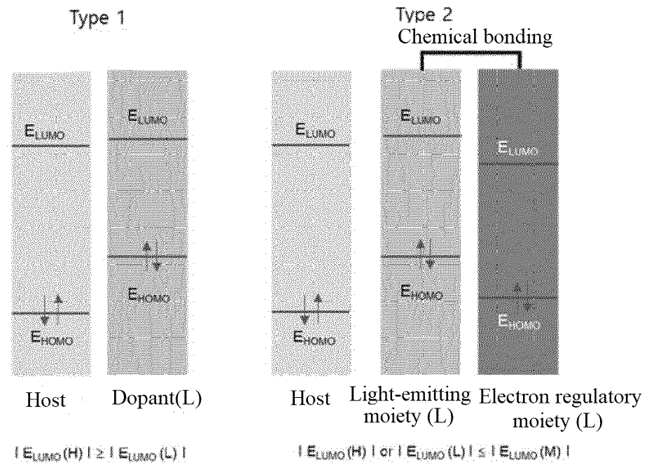

The HOMO-LUMO gap energy of a dopant is always smaller than the HOMO-LUMO gap energy of a host material, however, the positions of energy levels between the two materials are not always constant. In FIG. 1, E_{HOMO} represents the HOMO energy level of each material, and E_{LUMO} represents the LUMO energy level of each material.

Type 1 shows a comparison between energy levels of a dopant and a host according to one example. Type 1 is a case in which the HOMO energy level of a dopant is higher than the HOMO energy level of a host, and general hosts and dopants correspond to this type. Holes are directly injected into a light-emitting layer through a hole transport layer, and electrons are injected into the light-emitting layer through an electron transport layer from the opposite side. Since holes and electrons are injected from opposite sides of the light-emitting layer having a thickness of 200 Å to 500 Å, the holes are trapped in the dopant before the two charges meet to form excitons.

The LUMO energy level of a dopant is generally higher than the LUMO energy level of a host. Accordingly, it may be considered that electrons migrate along the LUMO energy level of the host regardless of the LUMO energy level of the dopant. In other words, hole migration in the light-emitting layer may be controlled by the doping amount of the dopant, however, it is impossible to control electron migration.

Type 2 shows a comparison between the energy level of each moiety in the complex light-emitting compound including the light-emitting moiety and the electron regulatory moiety and the energy level of a host. The complex light-emitting compound is formed to include the light-emitting moiety and the electron regulatory moiety by linking the electron regulatory moiety to the dopant that is a light-emitting material in Type 1, and Type 1 and Type 2 may be compared as such. The LUMO energy level of the electron regulatory moiety is lower than the LUMO energy level of the light-emitting moiety.

The electron regulatory moiety of the complex light-emitting compound may affect the migration of electrons injected into the light-emitting layer. Accordingly, the complex light-emitting compound may balance charges between holes and electrons inside the light-emitting layer to increase luminous efficiency or improve device stability. For example, by properly adjusting a doping concentration of the complex light-emitting compound depending on materials forming the light-emitting layer and each organic layer of an organic light-emitting diode, electron migration into the light-emitting layer may be controlled, and a charge balance between holes and electrons may be maximized inside the light-emitting layer.

The complex light-emitting compound may have a structure divided into three regions including a first portion corresponding to the electron regulatory moiety, a second portion corresponding to the linking portion, and a third portion corresponding to the light-emitting moiety, and the structure may be represented as follows.
[First portion]-[Second portion]-[Third portion]

The complex light-emitting compound may be designed such that an electron regulatory compound that induces the first portion and a light-emitting compound that induces the third portion are selected so as to satisfy the pre-determined conditions described above when they chemically bond, and the linking portion corresponding to the second portion is formed to link these.

The first role of the electron regulatory moiety, the first portion, is to maintain a charge balance by regulating electron migration inside the light-emitting layer.

The second role of the electron regulatory moiety, the first portion, is to reduce the probability that the light-emitting moiety in an excited state interacts with surrounding other molecules by spatially protecting a certain portion of the light-emitting moiety.

The third role of the electron regulatory moiety, the first portion, is to minimize a concentration quenching phenomenon between the dopants by reducing interaction between the light-emitting moieties.

In addition, the HOMO-LUMO gap energy of the electron regulatory moiety needs to be larger than maximum emission wavelength energy of the light-emitting moiety. In this case, the light-emitting moiety may be stabilized as described above without the electron regulatory moiety receiving energy from the light-emitting moiety. Meanwhile, when the HOMO-LUMO gap energy of the electron regulatory moiety is smaller than maximum emission wavelength energy of the light-emitting moiety, energy of the light-emitting moiety is transferred to the electron regulatory moiety, causing a problem of emitting light in the electron regulatory moiety.

The HOMO energy may be measured using methods such as cyclic voltammetry (CV), ultraviolet photoelectron spectroscopy (UPS) and AC2, and the LUMO energy may be measured using UV absorption spectrum or cyclic voltammetry (CV). From the difference between the measured HOMO energy and LUMO energy, the HOMO-LUMO gap energy may be calculated.

The maximum emission wavelength energy means a wavelength having the largest number of photons among the light energies emitted when a compound is excited with a maximum absorption wavelength of the compound. The maximum emission wavelength energy is measured by dissolving the light-emitting compound in an organic solvent such as toluene, methylene chloride or THF to have a concentration of about 2 micromoles.

The electron regulatory moiety may be designed using an aromatic ring having 6 to 50 carbon atoms or an aromatic hetero-fused ring having 5 to 50 carbon atoms, which satisfies the condition that the HOMO-LUMO gap energy of the electron regulatory moiety is larger than the maximum emission wavelength energy of the light-emitting moiety, and the LUMO energy level of the electron regulatory moiety is the same as or lower than the LUMO energy level of the light-emitting moiety, or those derived from organometallic compounds in which these and metals bond.

In the organometallic compound, the metal may be, for example, Cu, Fe, Ni, Co, Ir, Pt or the like. However, these are just an example, and the metal is not limited thereto.

In one embodiment, the electron regulatory moiety may be an aromatic ring having 6 to 50 carbon atoms having at least one substituent represented by a structure of the following Chemical Formula 1; or an aromatic hetero-fused ring having 5 to 50 carbon atoms having at least one substituent represented by the following Chemical Formula 1.

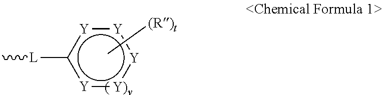

In Chemical Formula 1,
L is a single bond, or a divalent group selected from the group consisting of alkylene having 1 to 30 carbon atoms, cycloalkylene having 3 to 30 carbon atoms, heterocycloalkylene having 2 to 30 carbon atoms, alkyl silylene having 1 to 30 carbon atoms, cycloalkyl silylene having 3 to 30 carbon atoms, heterocycloalkyl silylene having 2 to 30 carbon atoms, aryl silylene having 1 to 30 carbon atoms, alkyl aryl silylene having 7 to 30 carbon atoms, cycloalkyl aryl silylene having 9 to 30 carbon atoms, heterocycloalkyl aryl silylene having 8 to 30 carbon atoms, oxygen, sulfur, a divalent group of aryl phosphine having 6 to 30 carbon atoms, a divalent group of aryl phosphine oxide having 6 to 30 carbon atoms, arylene having 6 to 30 carbon atoms, heteroarylene having 2 to 30 carbon atoms, and combinations thereof,
t is an integer of 0 to 5,
v is 0 or 1,
R″s are each independently selected from hydrogen, deuterium, alkyl having 1 to 30 carbon atoms, cycloalkyl having 3 to 30 carbon atoms, heterocycloalkyl having 2 to 30 carbon atoms, allyl having 3 to 30 carbon atoms, aryl having 6 to 30 carbon atoms unsubstituted or substituted with a third additional substituent, heteroaryl having 2 to 30 carbon atoms unsubstituted or substituted with a third additional substituent, alkyl amine having 1 to 30 carbon atoms, cycloalkylene amine having 3 to 30 carbon atoms, heterocycloalkylene amine having 2 to 30 carbon atoms, aryl amine having 6 to 30 carbon atoms unsubstituted or substituted with a third additional substituent, alkyl aryl amine having 7 to 30 carbon atoms unsubstituted or substituted with a third additional substituent, cycloalkyl aryl amine having 9 to 30 carbon atoms unsubstituted or substituted with a third additional substituent, heterocycloalkyl aryl amine having 8 to 30 carbon atoms unsubstituted or substituted with a third additional substituent, halogen, CN, alkoxy having 1 to 30 carbon atoms, aryloxy having 6 to 30 carbon atoms unsubstituted or substituted with a third additional substituent, alkyl silyl having 1 to 30 carbon atoms unsubstituted or substituted with a third additional substituent, cycloalkyl silyl having 3 to 30 carbon atoms unsubstituted or substituted with a third additional substituent, heterocycloalkyl silyl having 2 to 30 carbon atoms unsubstituted or substituted with a third additional substituent, aryl silyl having 6 to 30 carbon atoms unsubstituted or substituted with a third additional substituent, alkyl aryl silyl having 7 to 30 carbon atoms unsubstituted or substituted with a third additional substituent, cycloalkyl aryl silyl having 9 to 30 carbon atoms unsubstituted or substituted with a third additional substituent, heterocycloalkyl aryl silyl having 8 to 30 carbon atoms unsubstituted or substituted with a third additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine having 1 to 30 carbon atoms, aryl phosphine oxide having 1 to 30 carbon atoms, and combinations thereof, and herein, at least two R″s may be linked to each other to form a ring,
the third additional substituent is selected from alkyl having 1 to 30 carbon atoms, cycloalkyl having 3 to 30 carbon atoms, heterocycloalkyl having 2 to 30 carbon atoms, allyl having 3 to 30 carbon atoms, aryl having 6 to 30 carbon atoms, heteroaryl having 2 to 30 carbon atoms, alkyl amine having 2 to 30 carbon atoms, cycloalkylene amine having 3 to 30 carbon atoms, heterocycloalkylene amine having 2 to 30 carbon atoms, alkyl aryl amine having 7 to 30 carbon atoms, cycloalkyl aryl amine having 9 to 30 carbon atoms, heterocycloalkyl aryl amine having 8 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl aryl silyl having 7 to 30 carbon atoms, cycloalkyl aryl silyl having 9 to 30 carbon atoms, heterocycloalkyl aryl silyl having 8 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, and combinations thereof,
Ys are each independently nitrogen, oxygen, sulfur or carbon, and
[symbol] represents a linking site.

When at least two R″s are linked to form a ring in Chemical Formula 1, such a ring includes a fused ring. In addition, when two R″s are linked, a case in which any one R″ of the linked two is hydrogen, and, as the R″ that is the hydrogen is eliminated, the other R″ of the linked two directly bonds to Y to which the R″ that is the hydrogen is linked.

In one embodiment, the substituent represented by the structure of Chemical Formula 1 may be any one of structures of the following Chemical Formulae D-1 to D-13. In other words, the electron regulatory moiety may include structures represented by the following Chemical Formulae D-1 to D-13.

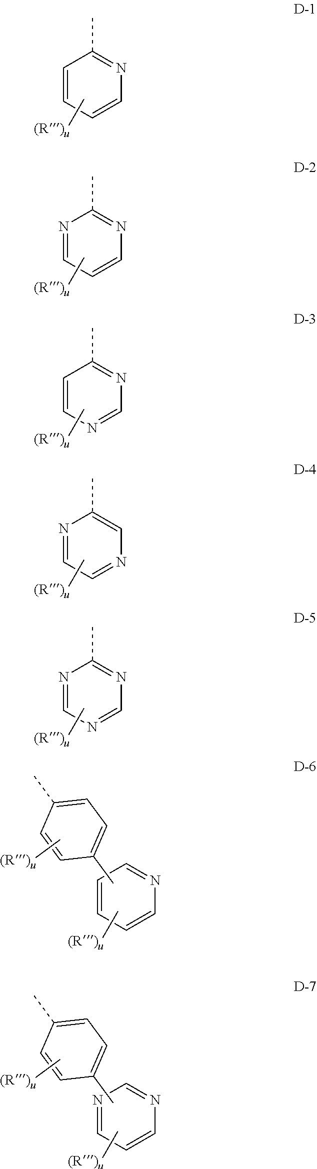

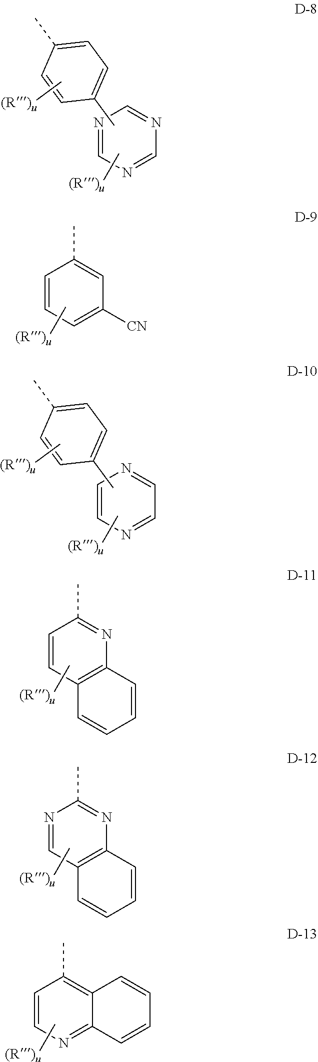

In Chemical Formulae D-1 to D-13,
X′″'s are each independently oxygen, nitrogen, sulfur or selenium,
R″'s are each independently selected from hydrogen, deuterium, alkyl having 1 to 30 carbon atoms, cycloalkyl having 3 to 20 carbon atoms, heterocycloalkyl having 2 to 20 carbon atoms, allyl having 3 to 30 carbon atoms, aryl having 6 to 30 carbon atoms, heteroaryl having 2 to 30 carbon atoms, alkyl amine having 2 to 30 carbon atoms, cycloalkyl amine having 3 to 20 carbon atoms, heterocycloalkyl amine having 2 to 20 carbon atoms, halogen, CN, alkyl silyl having 1 to 30 carbon atoms, cycloalkyl silyl having 3 to 20 carbon atoms, heterocycloalkyl silyl having 2 to 20 carbon atoms, aryl silyl having 6 to 30 carbon atoms, and combinations thereof,
us are each independently an integer of 0 to 20, and
a dotted line represents a linking site.

The first role of the second portion is to ensure that the electron regulatory moiety and the light-emitting moiety exist at a certain distance and space. When the electron regulatory moiety maintains a spatial position and angle that do not cause chemical interaction with the light-emitting moiety in this way, there is an advantage of significantly reducing the probability of chemical interaction and Coulomb interaction with surrounding other dopant materials, host materials and excitons by protecting a certain portion of the light-emitting moiety.

The second role of the second portion is to spatially minimize the HOMO or LUMO wave function overlap between the electron regulatory moiety and the light-emitting moiety. This is due to the fact that, when a wave function overlap occurs by the overlap of conjugated structures of the electron regulatory moiety and the light-emitting moiety, it may cause a problem of shifting an emission wavelength of the light-emitting moiety to a long wavelength, or reducing luminous efficiency.

The second portion may be formed by linking the electron regulatory moiety and the light-emitting moiety through a spiro bond.

In one embodiment, the electron regulatory moiety and the light-emitting moiety may be linked through a spiro bond using a carbon atom, a silicon atom, a Sn atom or a Ge atom as a spiro atom.

The electron regulatory moiety and the light-emitting moiety are linked through a spiro bond, and herein, the second portion corresponds to the spiro atom and the electron regulatory moiety or the light-emitting moiety is distinguished by not including the spiro atom.

The spiro bond forming the second portion needs to be formed so as not to significantly affect an electronic state of each of the electron regulatory moiety (first portion) and the light-emitting moiety (third portion). Herein, the “so as not to significantly affect” means that any one moiety of the first portion and the third portion should not change the HOMO energy level, the LUMO energy level or the HOMO-LUMO gap energy of another moiety by more than 0.2 eV. The criterion for defining the electronic state of each moiety in the complex light-emitting compound may be that the linking portion (second portion) is separated from each moiety (first portion or third portion) and not included, and the separated portion is in an independent compound state as a compound substituted with hydrogen. In other words, it may be compared with an independent compound state obtained by separating each of the moieties linked through the spiro bond, and substituting the places with two hydrogens. In other words, when separating the spiro bond, it may be compared with an independent compound state obtained by separating two bonds linked to the opposite moieties from the spiro atom, and substituting the places with two hydrogens. Herein, the change in the degree of conjugation of each compound due to the second portion (linking portion) and change in the electronic state caused therefrom are due to an effect of the second portion (linking portion), and are not considered to be due to an effect of the opposite moieties.

The light-emitting moiety, the third portion, emits light by receiving exciton energy formed in the host.

The light-emitting moiety may be induced from a light-emitting material (referred to as light-emitting compound in the present specification) capable of emitting light in an organic light-emitting diode by electron migration.

The light-emitting compound (light-emitting material) may be a compound that may be typically used as a dopant in an organic light-emitting diode. A dopant capable of expressing a desired color is selected as a light-emitting compound depending on the purpose, and the light-emitting moiety may be induced therefrom.

In one embodiment, the light-emitting moiety may have a conjugated structure with quantum efficiency of 50% or greater in a visible wavelength region of 400 nm to 700 nm.

In one embodiment, the light-emitting moiety may have a conjugated structure with quantum efficiency of 0.5% or greater in a near-infrared wavelength region of 700 nm to 2500 nm.

For example, the light-emitting moiety may be an aromatic ring having 6 to 50 carbon atoms or an aromatic hetero-fused ring having 5 to 50 carbon atoms, or may be derived from organometallic compounds in which these and metals bond.

In the organometallic compound, the metal may be, for example, Cu, Fe, Ni, Co, Ir, Pt or the like. However, these are just an example, and the metal is not limited thereto. It is a prerequisite that the organometallic compound that induces the light-emitting moiety is a light-emitting material capable of emitting light.

In one embodiment, the light-emitting compound and the light-emitting moiety include a conjugated structure forming a wave function of HOMO or LUMO, and the conjugated structure may include boron.

The light-emitting moiety may include carbon and hydrogen (herein, hydrogen is defined to include deuterium and tritium, that is, the light-emitting moiety may include at least one selected from the group consisting of hydrogen, deuterium, tritium and combinations thereof), and for example, may include a skeleton of pyrene, anthracene, fluorene, benzofluorene or benzoanthracene.

Specific examples of the light-emitting compound (or light-emitting material) may include the following compounds, but are not limited thereto.

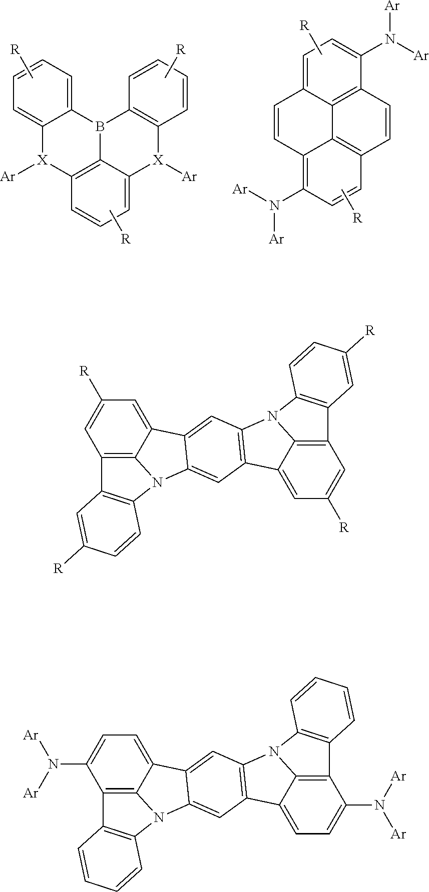

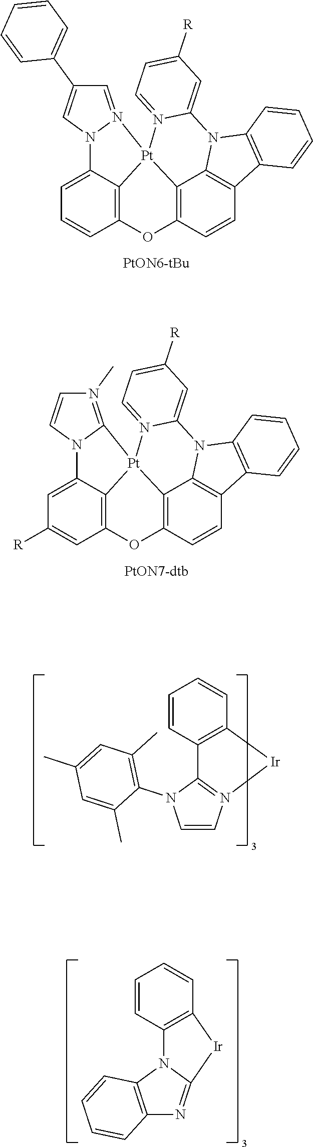

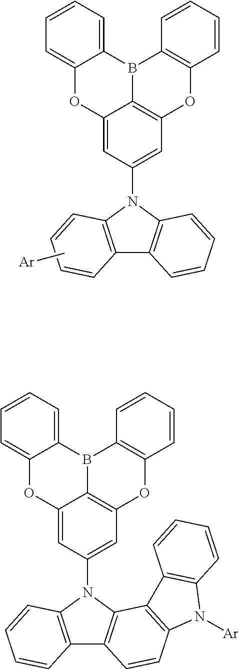

In the formulae, Ar and R may each be substituted or unsubstituted alkyl having 1 to 20 carbon atoms, substituted or unsubstituted cycloalkyl having 3 to 20 carbon atoms, substituted or unsubstituted heterocycloalkyl having 2 to 20 carbon atoms, substituted or unsubstituted aryl having 6 to 30 carbon atoms, substituted or unsubstituted heteroaryl having 2 to 30 carbon atoms, or substituted or unsubstituted aryl amine having 6 to 30 carbon atoms, and X is an element of nitrogen, oxygen, sulfur, carbon, silicon, Ge or P.

Thus, the light-emitting compound may include boron compounds substituted with nitrogen, oxygen, sulfur, carbon, silicon, Ge, P or the like, pyrene compounds, compounds having a conjugated structure including nitrogen, and the like, such as the compounds having the above-described structural formulae, but is not limited thereto.

In addition, materials known as a light-emitting material may be used as the light-emitting compound. For example, the light-emitting compound may include light-emitting bodies having a conjugated structure such as anthracene, perylene, tetracene, chrysene, coumarin and pyrromethene.

In one embodiment, the light-emitting compound and the light-emitting moiety include a conjugated structure forming a wave function of HOMO or LUMO, and the conjugated structure may include boron.

The light-emitting mechanism of the light-emitting moiety may include fluorescence that light is emitted from a singlet, phosphorescence that light is emitted from a triplet, and delayed fluorescence that light is emitted by transferring energy from a triplet to a singlet.

As described above, the complex light-emitting compound may be designed such that the electron regulatory moiety bonds to the light-emitting compound by being linked through the linking group.

When forming the complex light-emitting compound by linking the electron regulatory compound, which is induced to the electron regulatory moiety, to the light-emitting compound through the linking portion, substituents and the like included in the light-emitting compound or the electron regulatory compound may be properly modified for chemical bonding between these moieties or with the linking group to induce the light-emitting moiety and the electron regulatory moiety. Herein, the portion modified for chemical bonding does not significantly change properties such as inherent luminescence properties, band gap energy and energy efficiency of each of the electron regulatory compound and the light-emitting compound. For example, the light-emitting moiety may be formed by substituting a substituent of the light-emitting compound with another substituent for chemical bonding, however, the replaced substituent does not significantly affect properties such as luminescence properties, band gap energy and energy efficiency of the light-emitting moiety.

The phrase “does not significantly affect” means that it does not deviate from the detailed description on the electron regulatory moiety and the light-emitting moiety described in the present specification. Specifically, substituents and the like of the electron regulatory compound and the light-emitting compound being “properly” modified during chemical bonding means that the produced complex light-emitting compound complies with the description in the present specification. In other words, it means effects of general substituents such as modifying a band gap of the light-emitting compound or increasing quantum efficiency by modifying substituents, without causing drastic changes such as reducing band gap energy, efficiency and the like by 80% or more.

In one embodiment, the electron regulatory moiety may have band gap energy of 1 eV to 4.7 eV, and the light-emitting moiety may have band gap energy of 0.5 eV to 3.5 eV.

The electron regulatory moiety of the complex light-emitting compound increases luminous efficiency and improve device stability by balancing charges between holes and electrons inside the light-emitting layer without significantly affecting inherent luminescence properties of the light-emitting moiety. In addition, the electron regulatory moiety significantly reduces the probability of chemical interaction and Coulomb interaction with surrounding other dopant materials, host materials and excitons by protecting a certain portion of the light-emitting moiety while maintaining spatial position and angle that do not cause chemical interaction with the light-emitting moiety.

For the above-mentioned reasons, the complex light-emitting compound may increase luminescence stability in driving the organic light-emitting diode device.

In one embodiment, the complex light-emitting compound may be any one of the following compounds.

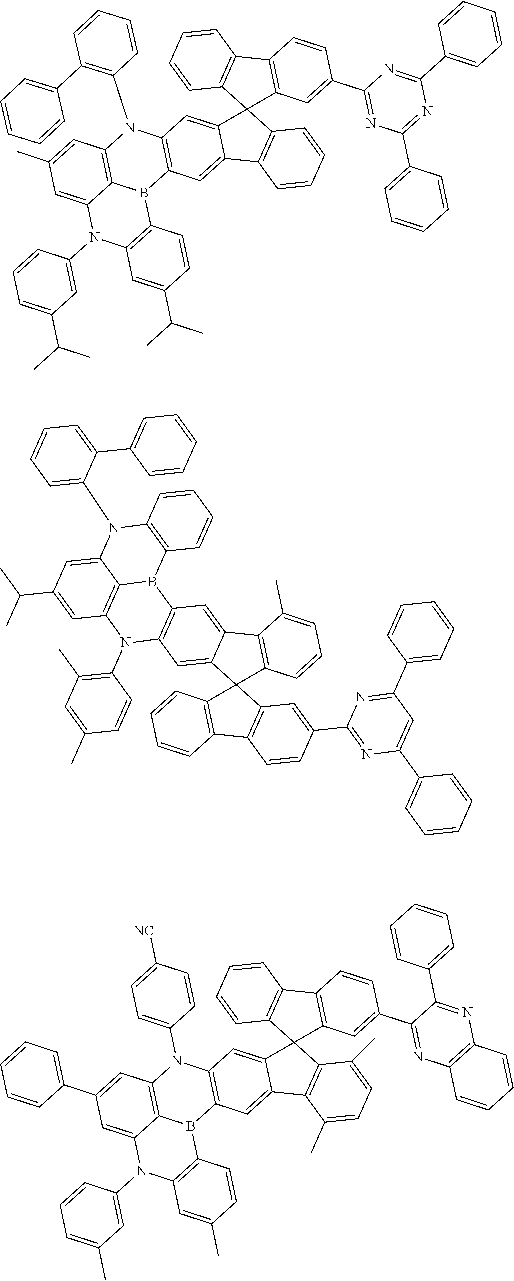 [SMILES: Cc1cc2c3c(c1)N(c1ccccc1-c1ccccc1)c1cc4c(cc1B3c1ccc(C(C)C)cc1N2c1cccc(C(C)C)c1)-c1ccccc1C41c2ccccc2-c2ccc(-c3nc(-c4ccccc4)nc(-c4ccccc4)n3)cc21 ; Cc1ccc(N2c3cc4c(cc3B3c5ccccc5N(c5ccccc5-c5ccccc5)c5cc(C(C)C)cc2c53)-c2c(C)cccc2C42c3ccccc3-c3ccc(-c4nc(-c5ccccc5)cc(-c5ccccc5)n4)cc32)c(C)c1 ; Cc1cccc(N2c3cc(C)ccc3B3c4cc5c(cc4N(c4ccc(C#N)cc4)c4cc(-c6ccccc6)cc2c43)C2(c3ccccc3-c3ccc(-c4nc6ccccc6nc4-c4ccccc4)cc32)c2c(C)ccc(C)c2-5)c1]

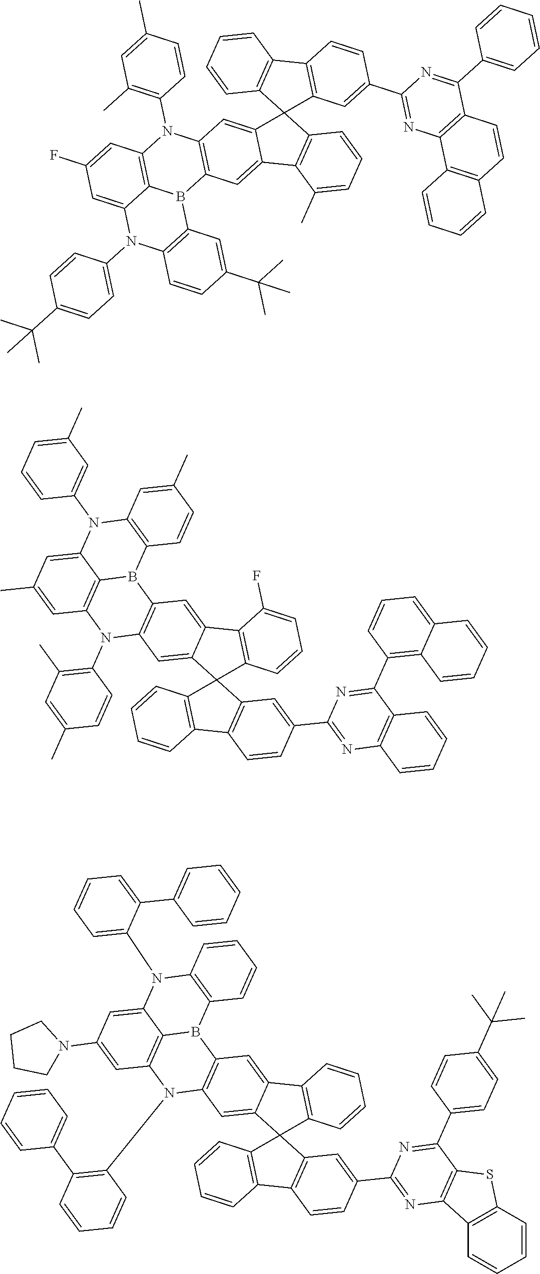 [SMILES: Cc1ccc(N2c3cc4c(cc3B3c5cc(C(C)(C)C)ccc5N(c5ccc(C(C)(C)C)cc5)c5cc(F)cc2c53)-c2c(C)cccc2C42c3ccccc3-c3ccc(-c4nc(-c5ccccc5)c5ccc6ccccc6c5n4)cc32)c(C)c1 ; Cc1cccc(N2c3cc(C)ccc3B3c4cc5c(cc4N(c4ccc(C)cc4C)c4cc(C)cc2c43)C2(c3ccccc3-c3ccc(-c4nc(-c6cccc7ccccc67)c6ccccc6n4)cc32)c2cccc(F)c2-5)c1 ; CC(C)(C)c1ccc(-c2nc(-c3ccc4c(c3)C3(c5ccccc5-4)c4ccccc4-c4cc5c(cc43)N(c3ccccc3-c3ccccc3)c3cc(N4CCCC4)cc4c3B5c3ccccc3N4c3ccccc3-c3ccccc3)nc3c2sc2ccccc23)cc1]

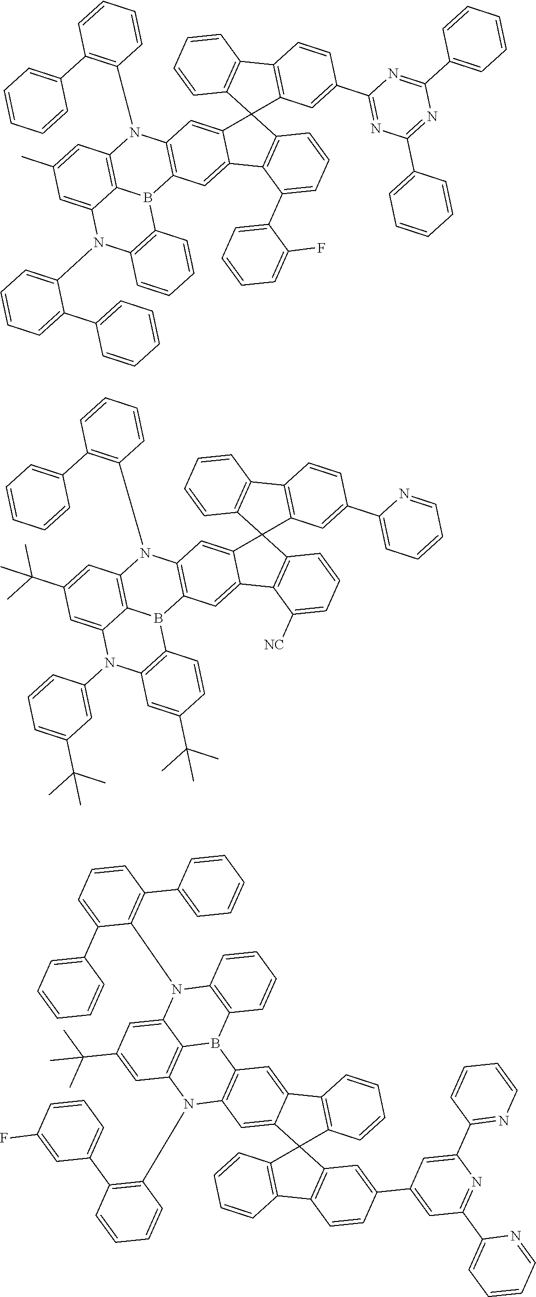

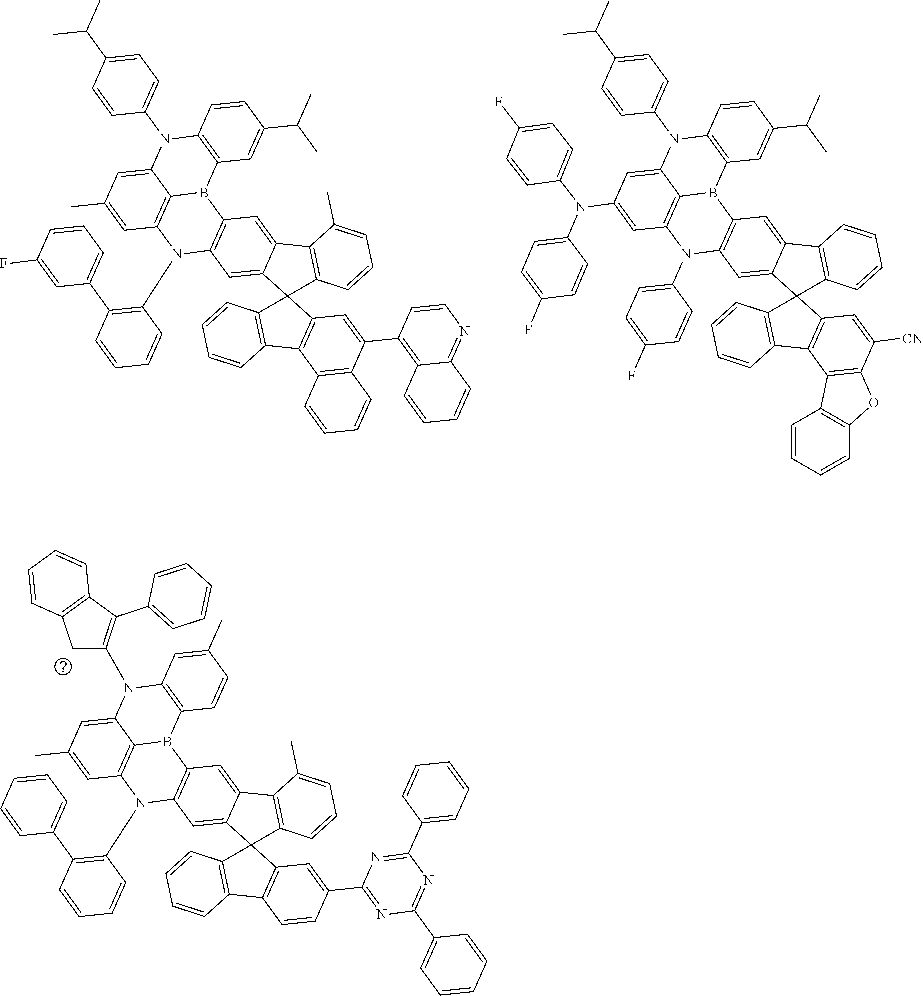 [SMILES: Cc1cc2c3c(c1)N(c1ccccc1-c1cccc(F)c1)c1cc4c(cc1B3c1cc(C(C)C)ccc1N2c1ccc(C(C)C)cc1)-c1c(C)cccc1C41c2ccccc2-c2c1cc(-c1ccnc3ccccc13)c1ccccc21 ; CC(C)c1ccc(N2c3ccc(C(C)C)cc3B3c4cc5c(cc4N(c4ccc(F)cc4)c4cc(N(c6ccc(F)cc6)c6ccc(F)cc6)cc2c43)C2(c3ccccc3-5)c3ccccc3-c3c2cc(C#N)c2oc4ccccc4c32)cc1 ; Cc1ccc2c(c1)N(C1=C(c3ccccc3)c3ccccc3C1)c1cc(C)cc3c1B2c1cc2c(cc1N3c1ccccc1-c1ccccc1)C1(c3ccccc3-c3ccc(-c4nc(-c5ccccc5)nc(-c5ccccc5)n4)cc31)c1cccc(C)c1-2]

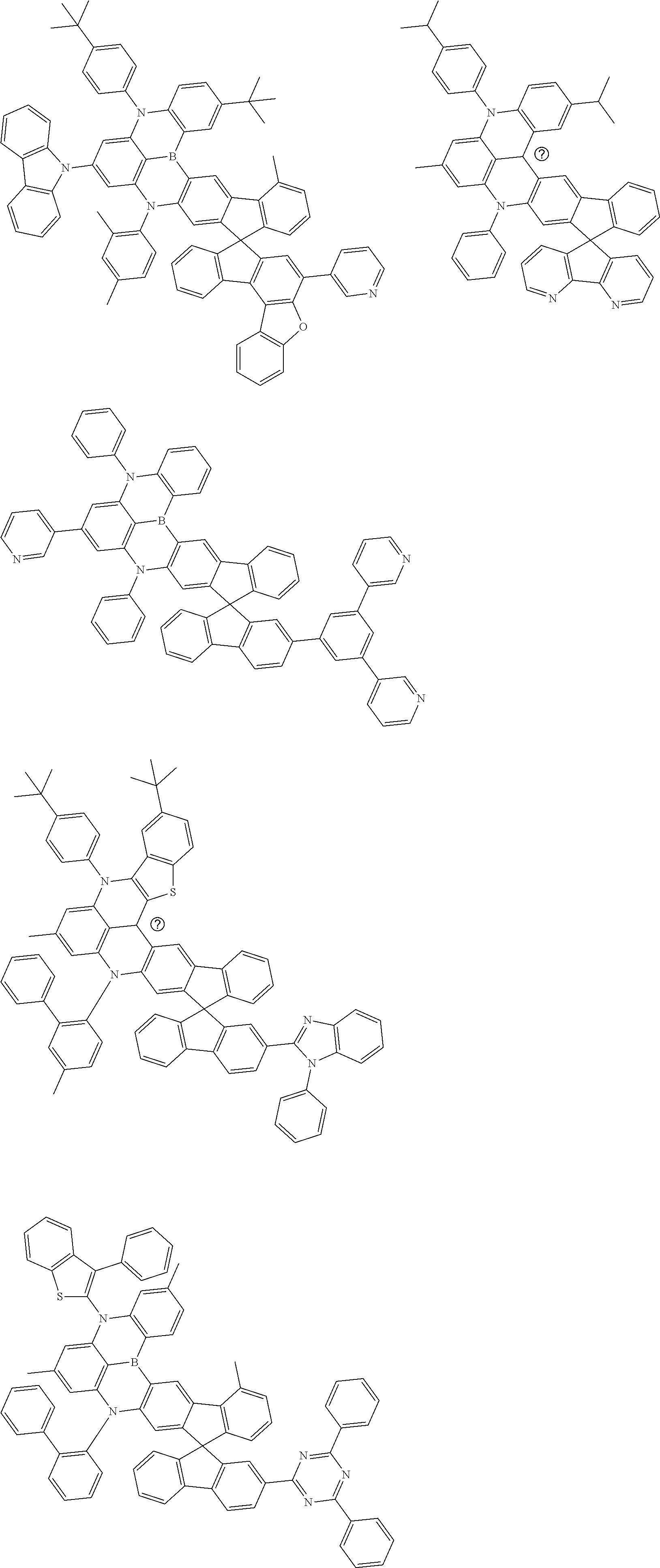

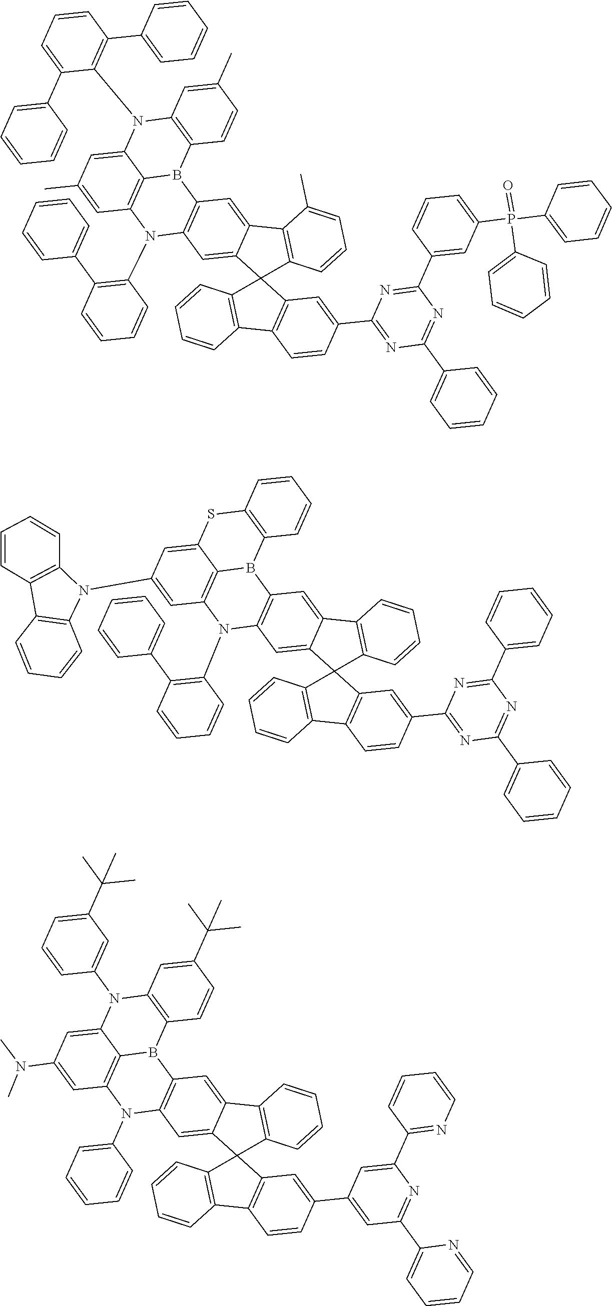 [SMILES: Cc1ccc2c(c1)N(c1c(-c3ccccc3)cccc1-c1ccccc1)c1cc(C)cc3c1B2c1cc2c(cc1N3c1ccccc1-c1ccccc1)C1(c3ccccc3-c3ccc(-c4nc(-c5ccccc5)nc(-c5cccc(P(=O)(c6ccccc6)c6ccccc6)c5)n4)cc31)c1cccc(C)c1-2 ; c1ccc(-c2nc(-c3ccccc3)nc(-c3ccc4c(c3)C3(c5ccccc5-4)c4ccccc4-c4cc5c(cc43)N(c3ccccc3-c3ccccc3)c3cc(-n4c6ccccc6c6ccccc64)cc4c3B5c3ccccc3S4)n2)cc1 ; CN(C)c1cc2c3c(c1)N(c1ccccc1)c1cc4c(cc1B3c1ccc(C(C)(C)C)cc1N2c1cccc(C(C)(C)C)c1)-c1ccccc1C41c2ccccc2-c2ccc(-c3cc(-c4ccccn4)nc(-c4ccccn4)c3)cc21]

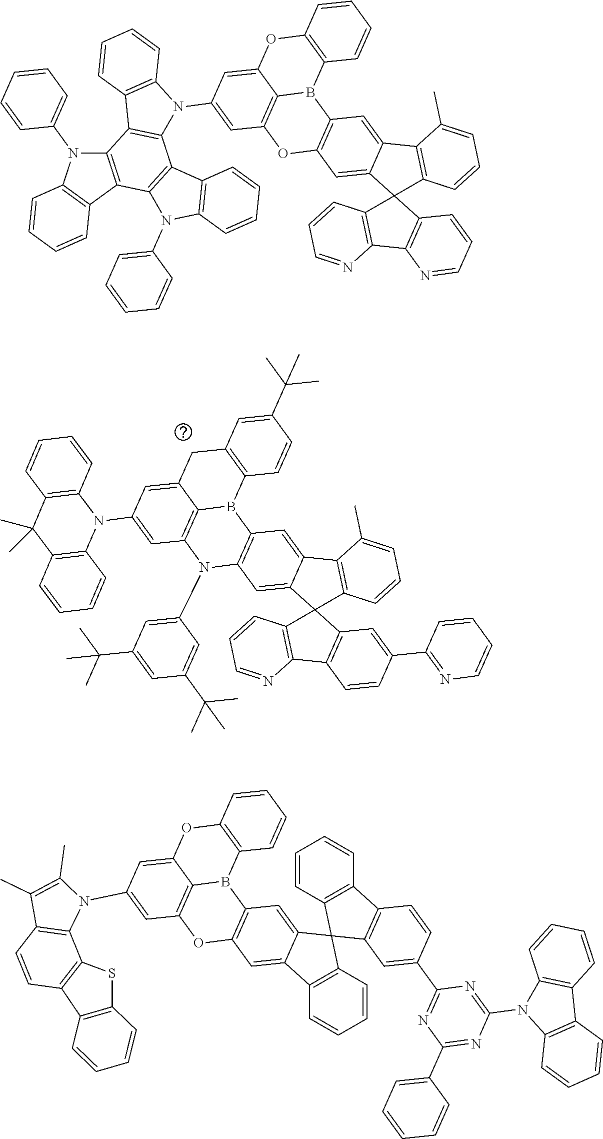 [SMILES: Cc1cccc2c1-c1cc3c(cc1C21c2cccnc2-c2ncccc21)Oc1cc(-n2c4ccccc4c4c5c(c6ccccc6n5-c5ccccc5)c5c(c6ccccc6n5-c5ccccc5)c42)cc2c1B3c1ccccc1O2 ; Cc1cccc2c1-c1cc3c(cc1C21c2cc(-c4ccccn4)ccc2-c2ncccc21)N(c1cc(C(C)(C)C)cc(C(C)(C)C)c1)c1cc(N2c4ccccc4C(C)(C)c4ccccc42)cc2c1B3c1ccc(C(C)(C)C)cc1C2 ; Cc1c(C)n(-c2cc3c4c(c2)Oc2cc5c(cc2B4c2ccccc2O3)C2(c3ccccc3-c3ccc(-c4nc(-c6ccccc6)nc(-n6c7ccccc7c7ccccc76)n4)cc32)c2ccccc2-5)c2c1ccc1c3ccccc3sc12]

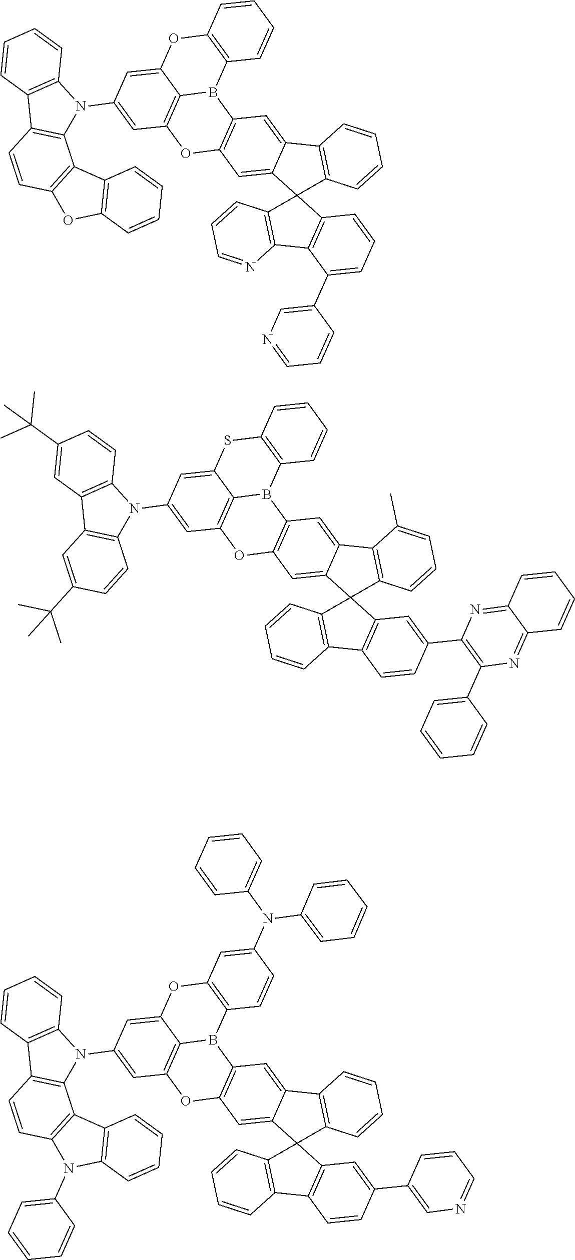

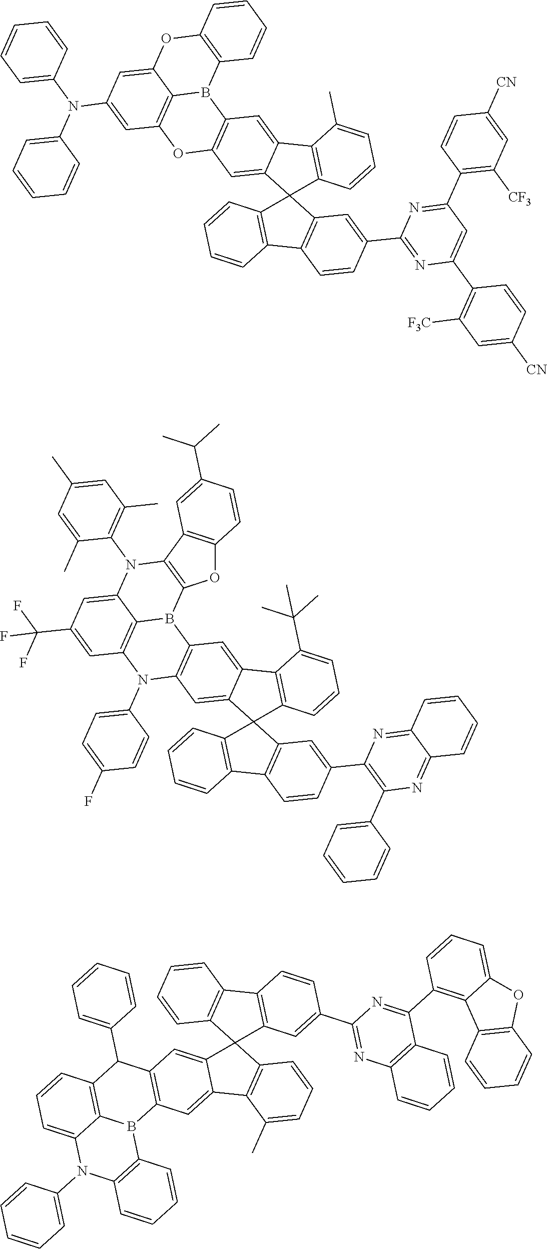 [SMILES: Cc1cccc2c1-c1cc3c(cc1C21c2ccccc2-c2ccc(-c4nc(-c5ccc(C#N)cc5C(F)(F)F)cc(-c5ccc(C#N)cc5C(F)(F)F)n4)cc21)Oc1cc(N(c2ccccc2)c2ccccc2)cc2c1B3c1ccccc1O2 ; Cc1cc(C)c(N2c3cc(C(F)(F)F)cc4c3B(c3cc5c(cc3N4c3ccc(F)cc3)C3(c4ccccc4-c4ccc(-c6nc7ccccc7nc6-c6ccccc6)cc43)c3cccc(C(C)(C)C)c3-5)c3oc4ccc(C(C)C)cc4c32)c(C)c1 ; Cc1cccc2c1-c1cc3c(cc1C21c2ccccc2-c2ccc(-c4nc(-c5cccc6oc7ccccc7c56)c5ccccc5n4)cc21)C(c1ccccc1)c1cccc2c1B3c1ccccc1N2c1ccccc1]

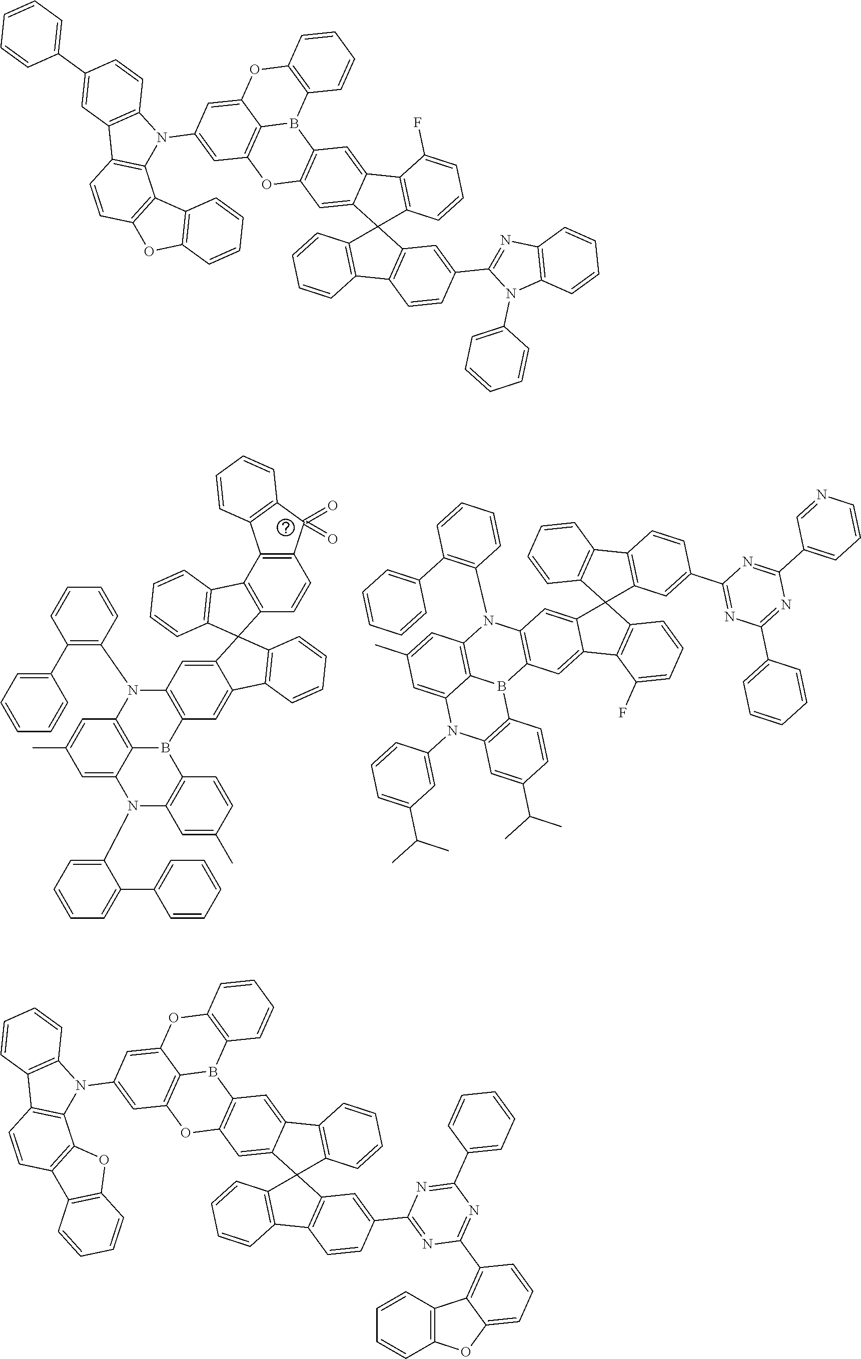

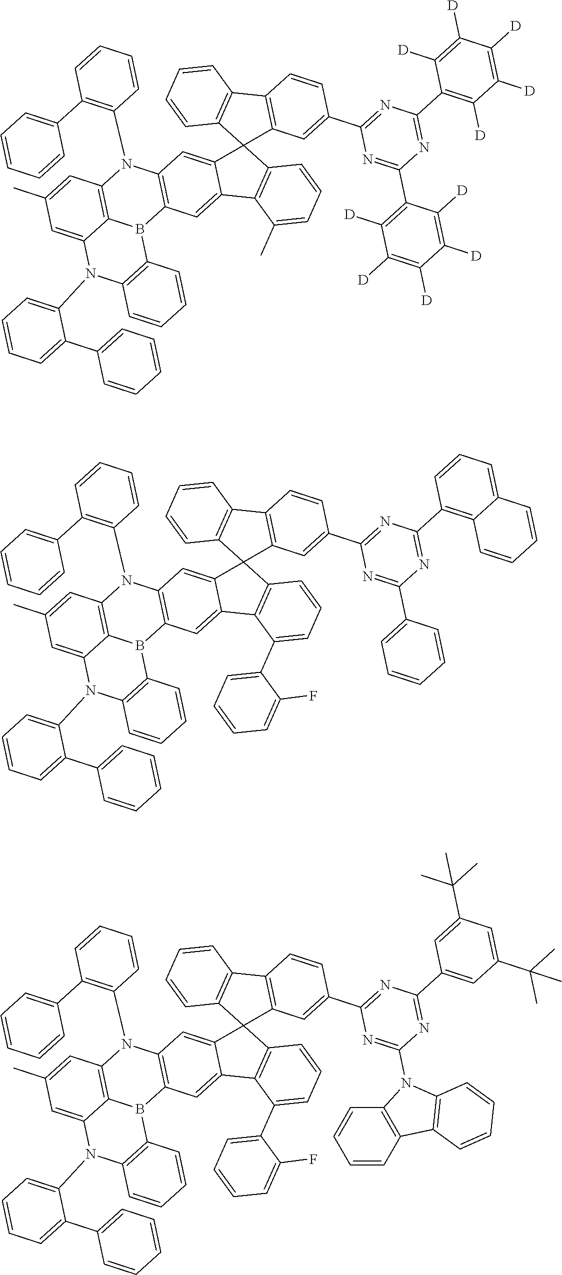

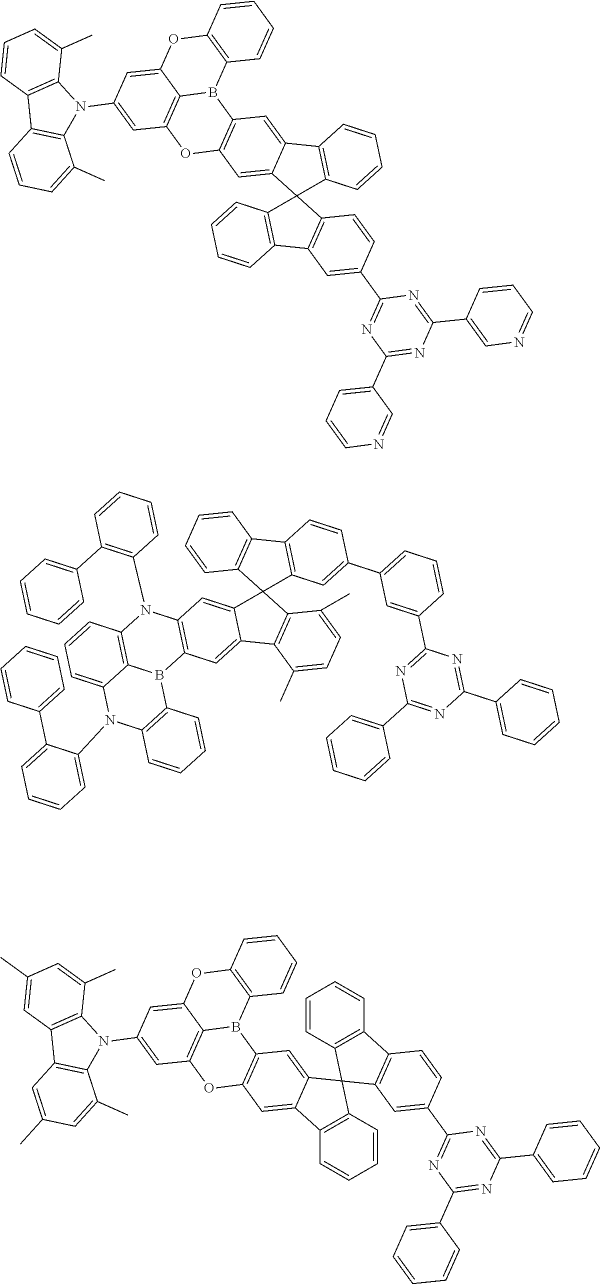 [SMILES: Cc1cccc2c3cccc(C)c3n(-c3cc4c5c(c3)Oc3cc6c(cc3B5c3ccccc3O4)-c3ccccc3C63c4ccccc4-c4cc(-c5nc(-c6cccnc6)nc(-c6cccnc6)n5)ccc43)c12 ; Cc1ccc(C)c2c1-c1cc3c(cc1C21c2ccccc2-c2ccc(-c4cccc(-c5nc(-c6ccccc6)nc(-c6ccccc6)n5)c4)cc21)N(c1ccccc1-c1ccccc1)c1cccc2c1B3c1ccccc1N2c1ccccc1-c1ccccc1 ; Cc1cc(C)c2c(c1)c1cc(C)cc(C)c1n2-c1cc2c3c(c1)Oc1cc4c(cc1B3c1ccccc1O2)C1(c2ccccc2-c2ccc(-c3nc(-c5ccccc5)nc(-c5ccccc5)n3)cc21)c1ccccc1-4]

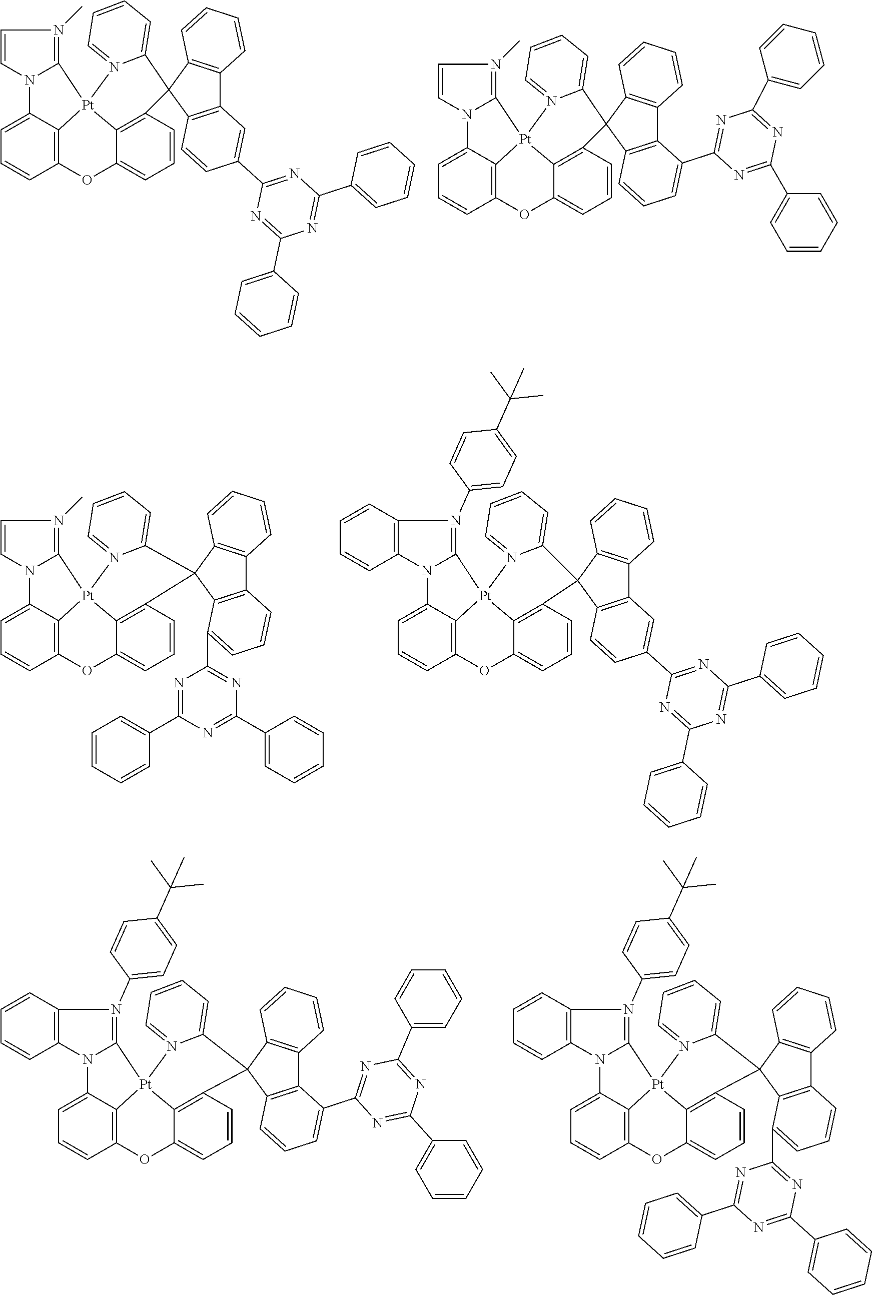

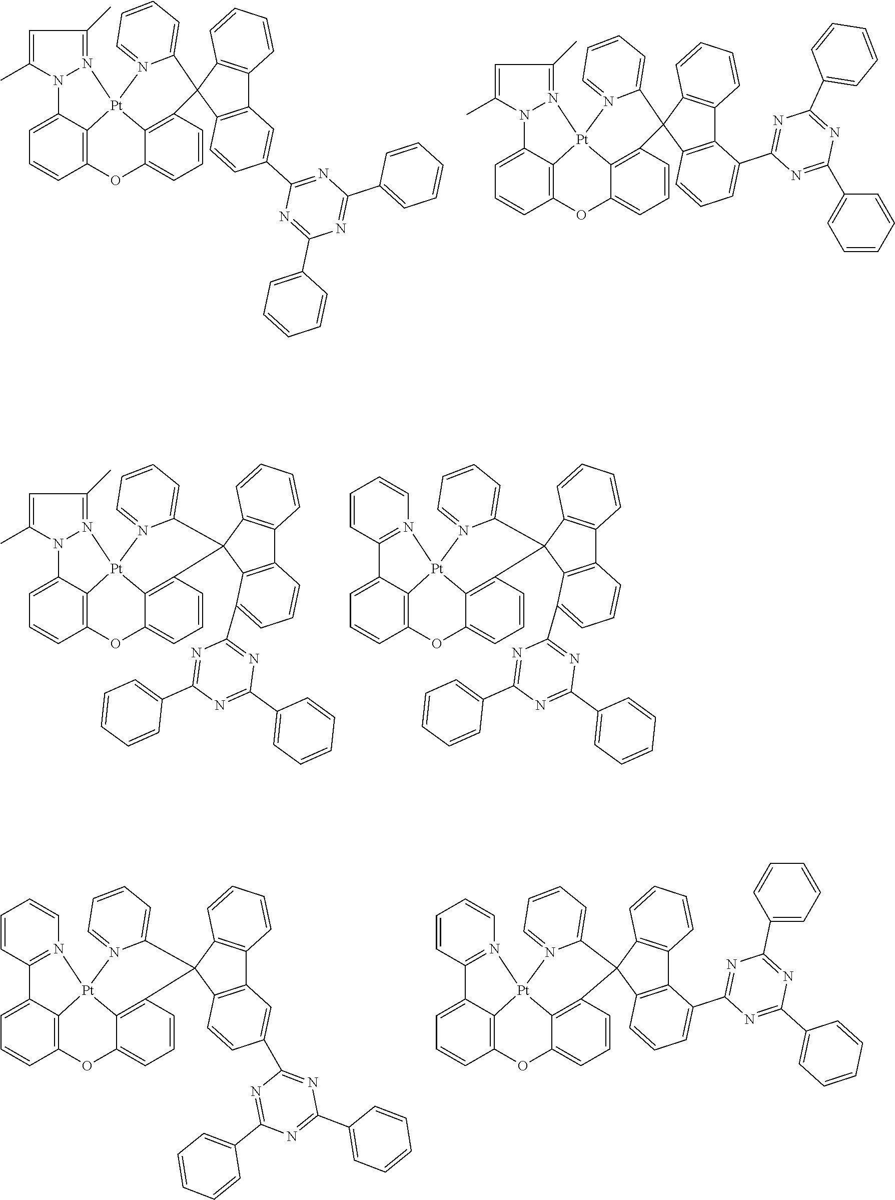

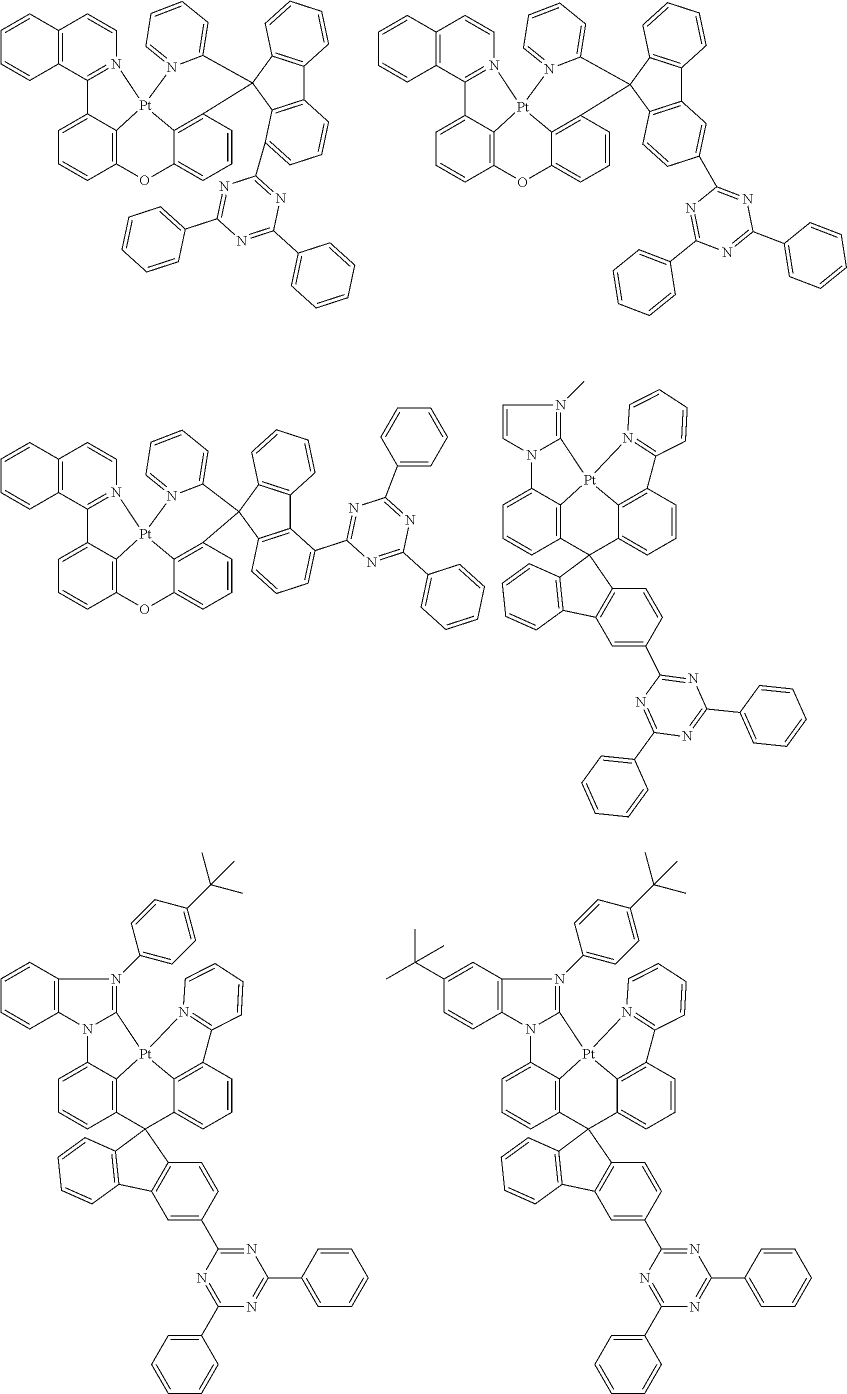

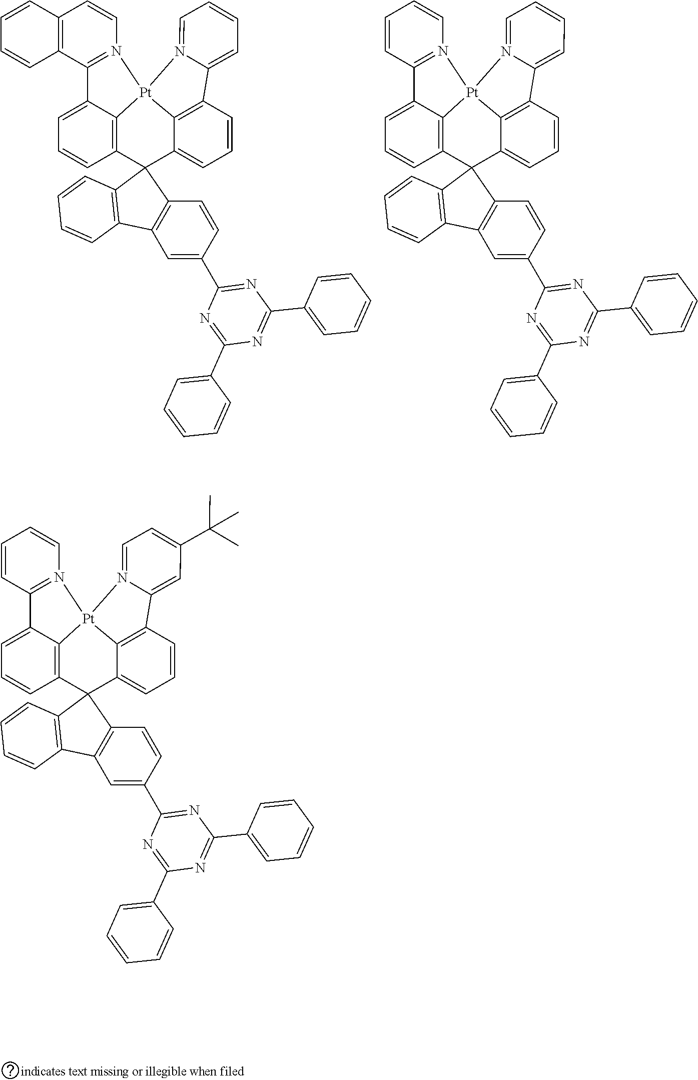

The compounds have structures in which the electron regulatory moiety and the light-emitting moiety are linked through a spiro bond, and have the electron regulatory moiety and the light-emitting moiety on both sides being divided based on the spiro atom.

In one embodiment, the light-emitting layer further includes a host, and the LUMO energy level of the electron regulatory moiety is lower than the LUMO energy level of the host.

The host may be a material generally known as a host material capable of forming a light-emitting layer.

For example, the light-emitting layer may be formed only with the complex light-emitting compound and the host.

In one embodiment, at least one type of the host may be included. When the light-emitting layer includes two or more types of hosts, the LUMO energy level of the electron regulatory moiety is lower than the LUMO energy level of at least one type of the host among the two or more types of hosts. Accordingly, when there are two or more types of hosts, the LUMO energy level of the one type of host having the highest LUMO energy level among the two or more types of hosts is compared with the LUMO energy level of the electron regulatory moiety. However, when a material that secondarily emits light by receiving energy from the light-emitting moiety of the complex light-emitting compound is included, the material that secondarily emits light is not classified as the host. The material that secondarily emits light may be an additional dopant to be described later.

In one embodiment, the light-emitting layer may include at least two types of the complex light-emitting compound.

In one embodiment, the complex light-emitting compound may include at least two of the electron regulatory moieties.

Specifically, the complex light-emitting compound may include at least two electron regulatory moieties linked to one light-emitting moiety, and in this case, two linking portions, which link each of the electron regulatory moieties to the light-emitting moiety, are formed in the complex light-emitting compound.

In one embodiment, the light-emitting layer may include at least two types of the electron regulatory moiety. For example, when there are two types of the electron regulatory moiety in the light-emitting layer, the two types of the electron regulatory moiety may be present in one complex light-emitting compound, or a plurality of the same or different complex light-emitting compound molecules may each include a different electron regulatory moiety. For example, when one complex light-emitting compound includes at least two electron regulatory moieties, the electron regulatory moieties may each be the same as or different from each other. For example, when the light-emitting layer includes one or more types of complex light-emitting compounds, the electron regulatory moiety included in each molecule of the complex light-emitting compounds may be the same as or different from each other.

When there are two or more types of electron regulatory moieties in the light-emitting layer, the LUMO energy levels of all the electron regulatory moieties are lower than the LUMO energy level of the host. For example, when there are two or more types of electron regulatory moieties, the LUMO energy levels of all the two or more types of electron regulatory moieties are compared with the LUMO energy level of the host.

When there are two or more types of electron regulatory moieties in the light-emitting layer and there are two or more types of the host, the LUMO energy levels of all types of the electron regulatory moiety present in the light-emitting layer are lower than the LUMO energy level of at least one type of the host. In other words, the LUMO energy levels of all types of the electron regulatory moiety present in the light-emitting layer are higher than the LUMO energy level of the host type having the highest LUMO energy level among the host types.

The light-emitting layer may further include an additional dopant. The additional dopant performs a role of re-emitting by absorbing luminescence energy of the light-emitting moiety. Accordingly, the maximum emission wavelength energy of the additional dopant is smaller than the highest emission wavelength energy of the light-emitting moiety. Luminescence of low energy may be obtained by using the additional dopant.

The highest emission wavelength energy means a wavelength having the largest photon energy in the emission spectrum. The highest emission wavelength is obtained from an onset value at the position where emission starts, and the maximum emission wavelength is obtained from the wavelength having the highest luminescence intensity.

Detailed description on the additional dopant is the same as the detailed description on the light-emitting compound (or light-emitting material) that induces the light-emitting moiety. For example, the additional dopant may be a publicly known dopant or a material known as light-emitting material.

In one embodiment,
the light-emitting layer may include the complex light-emitting compound in an amount of 0.1 mol % to 100 mol %, for example, 0.1 mol % to 50 mol %, however, the amount is not limited thereto.

In one embodiment, the molar ratio of the complex light-emitting compound to the host in the light-emitting layer may be 1:1.01 to 1000, and specifically 1:1.01 to 100.

In one embodiment, the molar ratio of the complex light-emitting compound to the additional dopant in the light-emitting layer may be 1:0.01 to 1, and specifically 1:0.01 to 0.1.

In one embodiment, the complex light-emitting compound may include at least one deuterium.

The organic light-emitting diode may further include a phosphorescent material in the light-emitting layer in order to further increase luminous efficiency of the light-emitting layer.

In one embodiment, the light-emitting layer may further include a phosphorescent material including Pt or Ir.

Compounds represented by the following structural formulae are examples of organometallic compounds commonly used as the phosphorescent material.

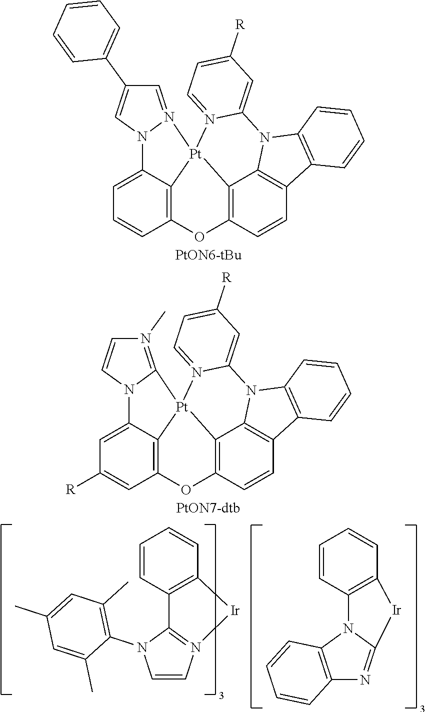

In the formulae, Rs may each be alkyl having 1 to 20 carbon atoms, cycloalkyl having 3 to 20 carbon atoms, heterocycloalkyl having 2 to 20 carbon atoms, aryl having 6 to 30 carbon atoms and the like.

The organic light-emitting diode may further include a delayed fluorescent material in the light-emitting layer in order to further increase luminous efficiency of the light-emitting layer.

In one embodiment, the light-emitting layer may further include a delayed fluorescent material in which an energy difference between a singlet and a triplet is 0.3 eV or greater.

Compounds represented by the following structural formulae are examples of the delayed fluorescent material commonly used.

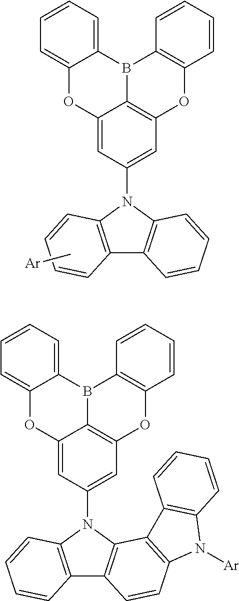

In the formulae, Ars may each be alkyl having 1 to 20 carbon atoms, cycloalkyl having 3 to 20 carbon atoms, heterocycloalkyl having 2 to 20 carbon atoms, aryl having 6 to 30 carbon atoms and the like.

The organic light-emitting diode may include one selected from the group consisting of a hole injection layer, a hole transport layer, an electron blocking layer, a hole blocking layer, an electron transport layer, an electron injection layer and combinations thereof as the organic layer.

In one embodiment, the organic light-emitting diode may sequentially include an anode, a hole injection layer (HIL), a hole transport layer (HTL), a light-emitting layer (EML), an electron transport layer (ETL) and a cathode.

The organic light-emitting diode may be a tandem-type organic light-emitting diode including a plurality of organic light-emitting units.

The plurality of organic light-emitting units may be sequentially laminated, and a charge generation layer (CGL) may be included between each of the organic light-emitting units. The charge generation layer is located between the organic light-emitting units so as to smoothly distribute charges to the light-emitting layer of each organic light-emitting unit.

In the tandem-type organic light-emitting diode, at least one organic light-emitting unit includes the light-emitting layer including the complex functional compound.

In the tandem-type organic light-emitting diode, detailed description on the complex functional compound is the same as the description stated above.

### Example

### Synthesis Example

### Synthesis of Comparative Compound 1

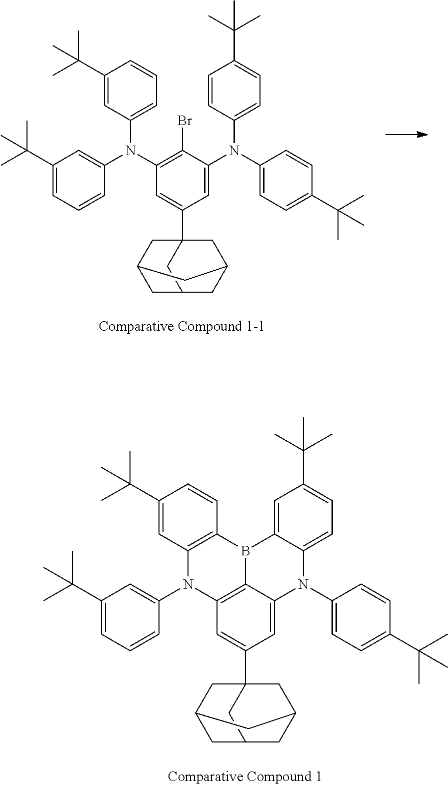

Comparative Compound 1-1 (8.48 g, 10.0 mmol) was dissolved in tertiary butylbenzene (32 ml), and then the solution was cooled to 0° C. A 2.5 M n-butyllithium solution (in hexane) (8.0 mL, 20.0 mmol) was added thereto under a nitrogen atmosphere, and the mixture was stirred for 3 hours at room temperature.

After that, the reaction solution was cooled to 0° C. again, boron tribromide (1.90 mL, 20.0 mmol) was added thereto, and the reaction solution was stirred for 0.5 hours at room temperature. The reaction solution was cooled to 0° C. again, and after adding N,N-diisopropylethyl amine (3.51 mL, 20.0 mmol) thereto, the reaction solution was stirred for 2 hours at 60° C. to 70° C.

The reaction solution was cooled to room temperature, and the organic layer was extracted with ethyl acetate. The solvent of the extracted organic layer was dried with MgSO₄, and then the dried organic layer was filtered. The filtrate was concentrated under reduced pressure, and then purified using a silica gel column chromatography (DCM/hexane) method.

After that, the purified material was recrystallized with a mixed solvent of DCM/acetone to obtain Comparative Compound 1 (1.05 g) in a yield of 12%.

MS (ACPI) m/z: 779 [M+H]

NMR: δH (500 MHz; CDCl₃; Me₄Si) 8.94 (s, 1H), 8.84 (d, J=10 Hz, 1H), 7.69 (d, 2H), 7.66-7.56 (m, 2H), 7.51-7.45 (d, 1H), 7.42 (s, 1H), 7.34-7.28 (m, 3H), 7.19 (d, 1H), 6.67 (s, J=8 Hz, 2H), 6.15 (d, 1H), 6.06 (s, 1H), 1.89 (s, 3H), 1.64 (d, 4H), 1.46 (s, 20H), 1.37 (s, 11H), 1.25 (s, 3H), 1.22 (s, 10H).

### Synthesis of Compound 2

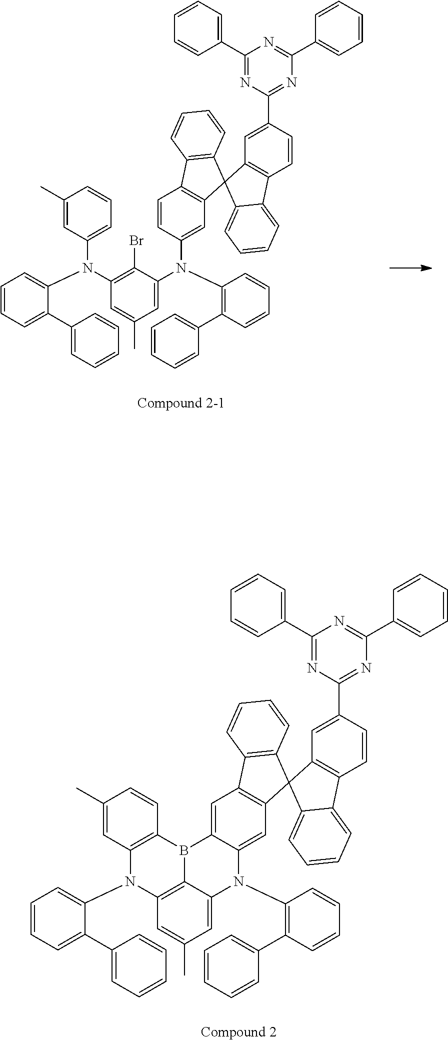 [SMILES: Cc1cccc(N(c2ccccc2-c2ccccc2)c2cc(C)cc(N(c3ccc4c(c3)C3(c5ccccc5-c5ccc(-c6nc(-c7ccccc7)nc(-c7ccccc7)n6)cc53)c3ccccc3-4)c3ccccc3-c3ccccc3)c2Br)c1 ; Cc1ccc2c(c1)N(c1ccccc1-c1ccccc1)c1cc(C)cc3c1B2c1cc2c(cc1N3c1ccccc1-c1ccccc1)C1(c3ccccc3-c3ccc(-c4nc(-c5ccccc5)nc(-c5ccccc5)n4)cc31)c1ccccc1-2]

Compound 2-1 (11.41 g, 10.0 mmol) of the present disclosure was dissolved in mesitylene (45 ml), and then the solution was cooled to −30° C. A 2.5 M n-butyllithium solution (in hexane) (8.0 mL, 20.0 mmol) was added thereto under a nitrogen atmosphere, and the mixture was stirred for 30 minutes at −30° C.

After that, the reaction solution was cooled to −30° C. again, boron tribromide (1.90 mL, 20.0 mmol) was added thereto, and the reaction solution was stirred for 2 hours at room temperature. 2,6-di-tert-butylpyridine (2.18 mL, 10.0 mmol) was added thereto at room temperature, and then the reaction solution was stirred for 8 hours at 170° C.

The reaction solution was cooled to room temperature, and the organic layer was extracted with ethyl acetate. The solvent of the extracted organic layer was dried with MgSO₄, and then the dried organic layer was filtered. The filtrate was concentrated under reduced pressure, and then purified using a silica gel column chromatography (DCM/hexane) method.

After that, the purified material was recrystallized with a mixed solvent of DCM/acetone to obtain Compound 2 (0.75 g) in a yield of 7%.

MS (ACPI) m/z: 1071 [M+H]

NMR: δH (400 MHz; CDCl₃; Me₄Si) 9.20 (dd, J=7.7, 2.7 Hz, 1H), 9.00-8.81 (m, 2H), 8.74-8.63 (m, 3H), 7.97 (dddd, J=41.1, 34.8, 16.0, 4.6 Hz, 4H), 7.77-7.63 (m, 3H), 7.62-7.28 (m, 12H), 7.17-6.85 (m, 10H), 6.83-6.34 (m, δH), 6.04-5.83 (m, 3H), 2.36 (s, 3H), 2.13 (s, 3H).

### Synthesis of Compound 3

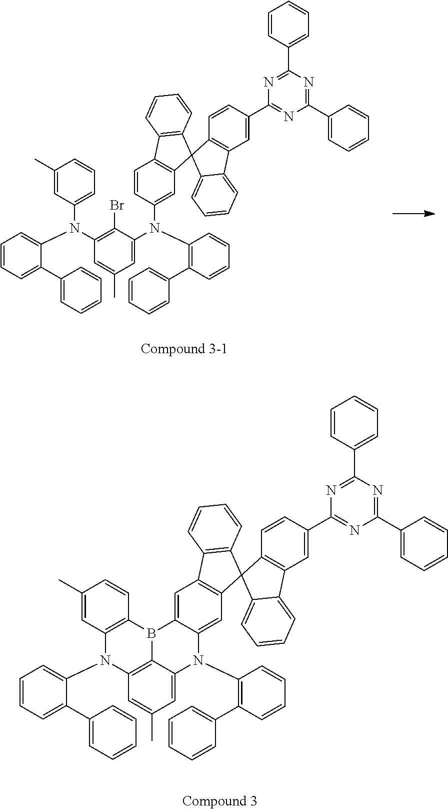 [SMILES: Cc1cccc(N(c2ccccc2-c2ccccc2)c2cc(C)cc(N(c3ccc4c(c3)C3(c5ccccc5-c5cc(-c6nc(-c7ccccc7)nc(-c7ccccc7)n6)ccc53)c3ccccc3-4)c3ccccc3-c3ccccc3)c2Br)c1 ; Cc1ccc2c(c1)N(c1ccccc1-c1ccccc1)c1cc(C)cc3c1B2c1cc2c(cc1N3c1ccccc1-c1ccccc1)C1(c3ccccc3-c3cc(-c4nc(-c5ccccc5)nc(-c5ccccc5)n4)ccc31)c1ccccc1-2]

Compound 3 was synthesized in the same manner as in Synthesis of Compound 2 described above, except that Compound 3-1 was used instead of Comparative Example Compound 2-1 in the same molar ratio as in Synthesis of Compound 2.

After that, Compound 3 (0.54 g) was obtained in a yield of 5%.

MS (ACPI) m/z: 1071 [M+H]

NMR: δH (400 MHz; CDCl₃; Me₄Si) 9.25-9.07 (m, 2H), 8.93-8.77 (m, 5H), 8.62-8.43 (m, 1H), 8.10-7.87 (m, 2H), 7.81-7.56 (m, 10H), 7.54-7.27 (m, 6H), 7.17-6.59 (m, 15H), 6.46 (ddd, J=7.1, 5.6, 4.2 Hz, 2H), 6.07-5.95 (m, 2H), 5.96-5.87 (m, 1H), 2.36 (s, 3H), 2.15 (d, J=2.1 Hz, 3H).

### Experimental Example 1. Measurement of HOMO-LUMO Energy Level

p-HOST, Compound 2 and Compound 3 were analyzed by differential pulse voltammetry (DPV) under a DMF solvent condition, and the results are shown in the following Table 1. Through this, it may be seen that the LUMO energy level of the electron regulatory moiety is lower than the LUMO energy level of p-HOST.

As the measurement device, Autolab Electrochemical Workstations PGSTAT101 Potentiostat/Galvanostat was used.

TABLE 1

| | | Compound 2 | | Compound 3 | |
|---|---|---|---|---|---|
| | | Light- | Electron | Light- | Electron |
| | p-HOST | Emitting | Regulatory | Emitting | Regulatory |
| | (H) | Moiety (L) | Moiety (M) | Moiety (L) | Moiety (M) |
| LUMO (eV) | −1.95 | −2.19 | −2.78 | −2.15 | −2.68 |
| HOMO (eV) | −5.56 | −5.22 | −5.75 | −5.22 | −5.71 |

### Manufacture of Organic Light-Emitting Diode

An ITO surface was treated with UV ozone for 3 minutes at atmospheric pressure.

In a 10⁻⁷ torr vacuum chamber, processes were performed in the following order to manufacture a device.

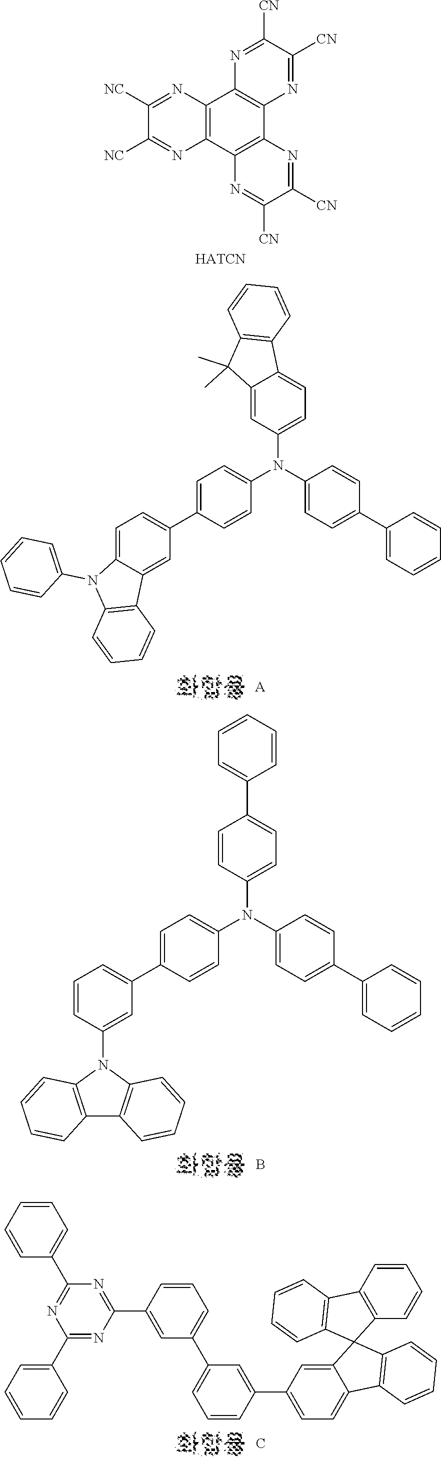

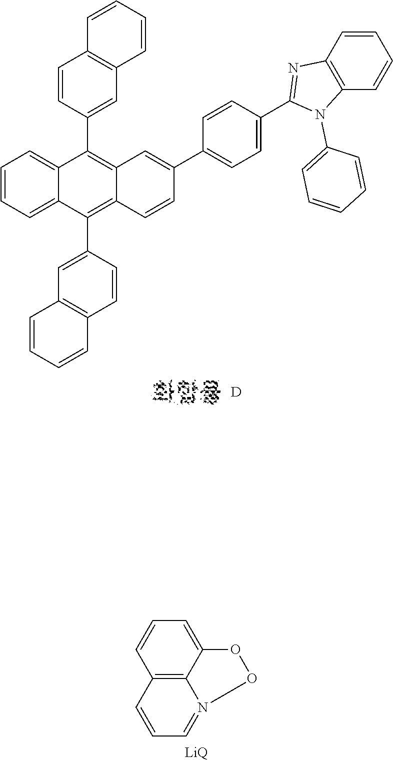

[symbol]

Compound

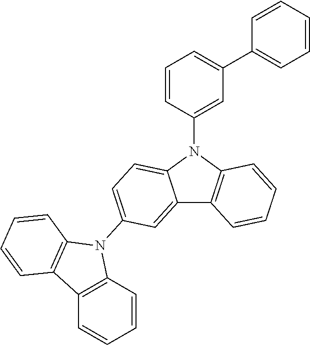 [SMILES: c1ccc(-c2cccc(-n3c4ccccc4c4cc(-n5c6ccccc6c6ccccc65)ccc43)c2)cc1]

p-HOST

### Comparative Example 1 (Device 1)

HATCN was deposited to a thickness of 50 Å as a hole injection material.

Compound A was deposited to a thickness of 600 Å as a hole transport material.

Compound B was deposited to a thickness of 50 Å as an electron blocking layer.

A light-emitting layer was deposited to a thickness of 200 Å using HOST-1 and by doping Comparative Compound 1 (5 mol %) thereto.

Compound C was deposited to a thickness of 50 Å as a hole blocking layer.

Compound D and LiQ in a ratio of 1:1 were deposited to a thickness of 300 Å as an electron transport layer.

LiQ was deposited to a thickness of 15 Å as an electron injection layer.

Al was deposited to a thickness of 500 Å as an electrode.

### Comparative Example 2 (Device 2)

Device 2 was manufactured in the same manner as in Comparative Example 1, except that the light-emitting layer of Device 1 was doped with Comparative Compound 1 (10 mol %).

### Example 1 (Device 3)

Device 3 was manufactured in the same manner as in Comparative Example 1, except that the light-emitting layer of Device 1 was doped with Compound 2 (10 mol %) instead of Comparative Compound 1.

### Example 2 (Device 4)

Device 4 was manufactured in the same manner as in Comparative Example 1, except that the light-emitting layer of Device 1 was doped with Compound 3 (10 mol %) instead of Comparative Compound 1.

Each of the devices was analyzed based on maximum luminous efficiency.

TABLE 2

| | | | | Doping | Voltage | Max_EQE | | | |
|---|---|---|---|---|---|---|---|---|---|
| Device | | Host | Dopant | % | (V) | (%) | CIE x | CIE y | λmax |
| Comparative | Device 1 | p-HOST | Comparative | 5% | 3.0 | 5.17 | 0.136 | 0.115 | 460 |
| Example | Device 2 | | Compound 1 | 10% | 2.80 | 5.92 | 0.141 | 0.140 | 460 |
| Example | Device 3 | | Compound 2 | 10% | 2.60 | 14.0 | 0.140 | 0.164 | 466 |
| | Device 4 | | Compound 3 | 10% | 2.70 | 15.07 | 0.142 | 0.171 | 466 |

As identified in Table 2, the device using the compound of the present disclosure shows excellent luminous efficiency and improved driving voltage properties. The host material used in manufacturing of the device enables hole migration better than electron migration. Specifically, when doping Comparative Compound 1, electrons are not readily injected, resulting in poor energy transfer to the dopant, and external quantum efficiency is only 5.17% and 5.92%. However, when introducing the electron regulatory moiety as in Compounds 2 and 3, electrons are readily injected into the electron regulatory moiety, increasing density in the light-emitting layer, and as a result, maximum quantum efficiency of 14.0% and 15.7%, respectively, was able to be obtained.

Hereinbefore, the present disclosure has been described with reference to accompanying drawings, however, the present disclosure is not limited by the embodiments and the drawings disclosed in the present specification, and it is obvious that various modifications may be made by those skilled in the art within the scope of technical ideas of the present disclosure. In addition, even when working effects obtained from the constitutions of the present disclosure are not explicitly described while describing the embodiments of the present disclosure, it is logical that effects predictable by the corresponding constitutions need to be acknowledged as well.

1. An organic light-emitting diode comprising:
a first electrode;
a second electrode; and
a light-emitting layer disposed between the first electrode and the second electrode,
wherein the light-emitting layer includes a complex light-emitting compound,
the complex light-emitting compound includes an electron regulatory moiety and a light-emitting moiety,
the complex light-emitting compound includes a linking portion that links the electron regulatory moiety and the light-emitting moiety through a spiro bond,
the electron regulatory moiety is a substituted or unsubstituted aromatic ring having 6 to 50 carbon atoms or aromatic hetero-fused ring having 5 to 50 carbon atoms, or derived from organometallic compounds in which these and metals bond,
HOMO-LUMO gap energy of the electron regulatory moiety is larger than maximum emission wavelength energy of the light-emitting moiety, and
a LUMO energy level of the electron regulatory moiety is the same as or lower than a LUMO energy level of the light-emitting moiety.

2. The organic light-emitting diode of claim 1, wherein the light-emitting moiety is induced from a light-emitting material.

3. The organic light-emitting diode of claim 1, wherein the light-emitting moiety has a conjugated structure with quantum efficiency of 50% or greater in a visible wavelength region of 400 nm to 700 nm.

4. The organic light-emitting diode of claim 1, wherein the light-emitting moiety has a conjugated structure with quantum efficiency of 0.5% or greater in a near-infrared wavelength region of 700 nm to 2500 nm.

5. The organic light-emitting diode of claim 1, wherein a light-emitting mechanism of the light-emitting moiety includes fluorescence that light is emitted from a singlet, phosphorescence that light is emitted from a triplet, and delayed fluorescence that light is emitted by transferring energy from a triplet to a singlet.

6. The organic light-emitting diode of claim 1, wherein the light-emitting layer further includes a host, and the LUMO energy level of the electron regulatory moiety is lower than the LUMO energy level of the host.

7. The organic light-emitting diode of claim 1, wherein the complex light-emitting compound includes at least one deuterium.

8. The organic light-emitting diode of claim 1, wherein the spiro atom is a carbon atom, a silicon atom, a Sn atom or a Ge atom.

9. The organic light-emitting diode of claim 1, wherein the electron regulatory moiety and the light-emitting moiety do not change the HOMO energy level, the LUMO energy level or the HOMO-LUMO band gap energy between each other by more than 0.2 eV while forming the linking portion through the spiro bond.

10. The organic light-emitting diode of claim 1, wherein the light-emitting moiety is an aromatic ring having 6 to 50 carbon atoms, an aromatic hetero-fused ring having 5 to 50 carbon atoms, or derived from organometallic compounds in which these and metals bond.

11. The organic light-emitting diode of claim 1, wherein the light-emitting moiety includes a conjugated structure forming a wave function of HOMO or LUMO, and the conjugated structure includes boron.

12. The organic light-emitting diode of claim 1, wherein the electron regulatory moiety is an aromatic ring having 6 to 50 carbon atoms having at least one substituent represented by a structure of the following Chemical Formula 1; or an aromatic hetero-fused ring having 5 to 50 carbon atoms having at least one substituent represented by the following Chemical Formula 1: 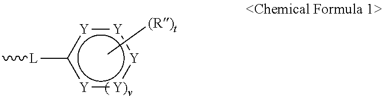
in Chemical Formula 1,
L is a single bond, or a divalent group selected from the group consisting of alkylene having 1 to 30 carbon atoms, cycloalkylene having 3 to 30 carbon atoms, heterocycloalkylene having 2 to 30 carbon atoms, alkyl silylene having 1 to 30 carbon atoms, cycloalkyl silylene having 3 to 30 carbon atoms, heterocycloalkyl silylene having 2 to 30 carbon atoms, aryl silylene having 1 to 30 carbon atoms, alkyl aryl silylene having 7 to 30 carbon atoms, cycloalkyl aryl silylene having 9 to 30 carbon atoms, heterocycloalkyl aryl silylene having 8 to 30 carbon atoms, oxygen, sulfur, a divalent group of aryl phosphine having 6 to 30 carbon atoms, a divalent group of aryl phosphine oxide having 6 to 30 carbon atoms, arylene having 6 to 30 carbon atoms, heteroarylene having 2 to 30 carbon atoms, and combinations thereof;
t is an integer of 0 to 5;
v is 0 or 1;
R″s are each independently selected from hydrogen, deuterium, alkyl having 1 to 30 carbon atoms, cycloalkyl having 3 to 30 carbon atoms, heterocycloalkyl having 2 to 30 carbon atoms, allyl having 3 to 30 carbon atoms, aryl having 6 to 30 carbon atoms unsubstituted or substituted with a third additional substituent, heteroaryl having 2 to 30 carbon atoms unsubstituted or substituted with a third additional substituent, alkyl amine having 1 to 30 carbon atoms, cycloalkylene amine having 3 to 30 carbon atoms, heterocycloalkylene amine having 2 to 30 carbon atoms, aryl amine having 6 to 30 carbon atoms unsubstituted or substituted with a third additional substituent, alkyl aryl amine having 7 to 30 carbon atoms unsubstituted or substituted with a third additional substituent, cycloalkyl aryl amine having 9 to 30 carbon atoms unsubstituted or substituted with a third additional substituent, heterocycloalkyl aryl amine having 8 to 30 carbon atoms unsubstituted or substituted with a third additional substituent, halogen, CN, alkoxy having 1 to 30 carbon atoms, aryloxy having 6 to 30 carbon atoms unsubstituted or substituted with a third additional substituent, alkyl silyl having 1 to 30 carbon atoms unsubstituted or substituted with a third additional substituent, cycloalkyl silyl having 3 to 30 carbon atoms unsubstituted or substituted with a third additional substituent, heterocycloalkyl silyl having 2 to 30 carbon atoms unsubstituted or substituted with a third additional substituent, aryl silyl having 6 to 30 carbon atoms unsubstituted or substituted with a third additional substituent, alkyl aryl silyl having 7 to 30 carbon atoms unsubstituted or substituted with a third additional substituent, cycloalkyl aryl silyl having 9 to 30 carbon atoms unsubstituted or substituted with a third additional substituent, heterocycloalkyl aryl silyl having 8 to 30 carbon atoms unsubstituted or substituted with a third additional substituent, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, aryl phosphine having 1 to 30 carbon atoms, aryl phosphine oxide having 1 to 30 carbon atoms, and combinations thereof, and herein, at least two R″s are optionally linked to each other to form a ring;
the third additional substituent is selected from alkyl having 1 to 30 carbon atoms, cycloalkyl having 3 to 30 carbon atoms, heterocycloalkyl having 2 to 30 carbon atoms, allyl having 3 to 30 carbon atoms, aryl having 6 to 30 carbon atoms, heteroaryl having 2 to 30 carbon atoms, alkyl amine having 2 to 30 carbon atoms, cycloalkylene amine having 3 to 30 carbon atoms, heterocycloalkylene amine having 2 to 30 carbon atoms, alkyl aryl amine having 7 to 30 carbon atoms, cycloalkyl aryl amine having 9 to 30 carbon atoms, heterocycloalkyl aryl amine having 8 to 30 carbon atoms, alkyl silyl having 1 to 30 carbon atoms, cycloalkyl silyl having 3 to 30 carbon atoms, heterocycloalkyl silyl having 2 to 30 carbon atoms, aryl silyl having 6 to 30 carbon atoms, alkyl aryl silyl having 7 to 30 carbon atoms, cycloalkyl aryl silyl having 9 to 30 carbon atoms, heterocycloalkyl aryl silyl having 8 to 30 carbon atoms, alkyl thiol having 1 to 30 carbon atoms, cycloalkyl thiol having 3 to 30 carbon atoms, heterocycloalkyl thiol having 2 to 30 carbon atoms, aryl thiol having 6 to 30 carbon atoms, and combinations thereof;
Ys are each independently nitrogen, oxygen, sulfur or carbon; and [symbol]
represents a linking site.

13. The organic light-emitting diode of claim 12, wherein the substituent represented by the structure of Chemical Formula 1 is represented by any one of structures of the following Chemical Formulae D-1 to D-13: 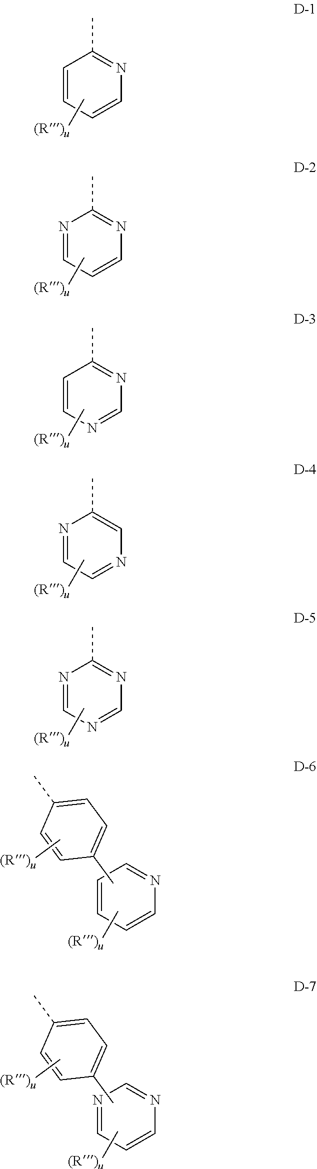 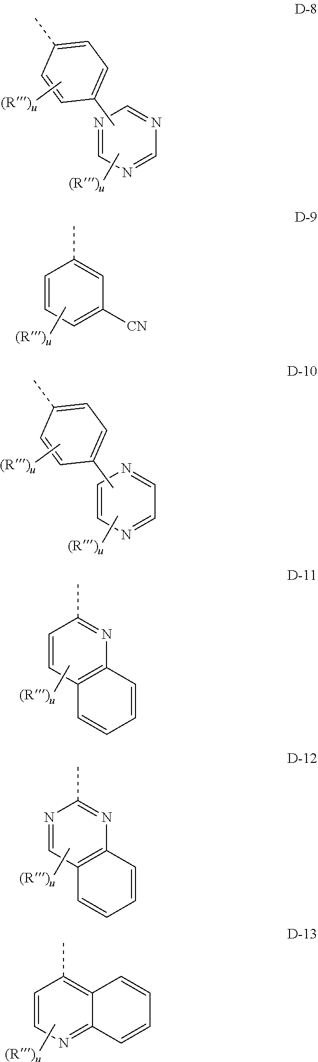
in Chemical Formulae D-1 to D-13,
X′″s are each independently oxygen, nitrogen, sulfur or selenium;
R′″s are each independently selected from hydrogen, deuterium, alkyl having 1 to 30 carbon atoms, cycloalkyl having 3 to 20 carbon atoms, heterocycloalkyl having 2 to 20 carbon atoms, allyl having 3 to 30 carbon atoms, aryl having 6 to 30 carbon atoms, heteroaryl having 2 to 30 carbon atoms, alkyl amine having 2 to 30 carbon atoms, cycloalkyl amine having 3 to 20 carbon atoms, heterocycloalkyl amine having 2 to 20 carbon atoms, halogen, CN, alkyl silyl having 1 to 30 carbon atoms, cycloalkyl silyl having 3 to 20 carbon atoms, heterocycloalkyl silyl having 2 to 20 carbon atoms, aryl silyl having 6 to 30 carbon atoms, and combinations thereof;
us are each independently an integer of 0 to 20; and
a dotted line represents a linking site.

14. The organic light-emitting diode of claim 1, wherein the light-emitting layer includes at least two types of the complex light-emitting compound.

15. The organic light-emitting diode of claim 1, wherein the complex light-emitting compound includes at least two of the electron regulatory moieties.

16. The organic light-emitting diode of claim 1, wherein the light-emitting layer further includes an additional dopant.

17. The organic light-emitting diode of claim 1, wherein the light-emitting layer further includes a phosphorescent material including Ir or Pt.

18. The organic light-emitting diode of claim 1, wherein the light-emitting layer further includes a delayed fluorescent material in which an energy difference between a singlet and a triplet is 0.3 eV or less.

19. The organic light-emitting diode of claim 1, which is a tandem-type organic light-emitting diode including a plurality of organic light-emitting units, wherein at least one of the plurality of organic light-emitting units includes the light-emitting layer.
